(19) United States
(12) Patent Application Publication
(10) Pub. No.: US 2023/0411234 A1
(43) Pub. Date: Dec. 21, 2023

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Shu-Shen Yeh, Taoyuan (TW); Yu Chen Lee, Hsinchu (TW); Po-Chen Lai, Hsinchu (TW); Po-Yao Lin, Zhudong Township (TW); Shin-Puu Jeng, Hsinchu (TW); Yu-Sheng Lin, Zhubei (TW); Chien-Hung Chen, Taipei (TW)

(21) Appl. No.: 17/825,748

(22) Filed: May 26, 2022

(51) Int. Cl. H01L 23/367; H01L 23/538; H01L 23/00

(52) U.S. Cl. CPC H01L 23/3675; H01L 23/5385; H01L 2224/32245; H01L 24/83; H01L 24/32

(57) ABSTRACT

A device includes a package substrate, an interposer having a first side bonded to the package substrate, a first die bonded to a second side of the interposer, the second side being opposite the first side, a ring on the package substrate, wherein the ring surrounds the first die and the interposer; and a heat spreader over and coupled to the ring and the first die, wherein a first coefficient of thermal expansion of a first material of the ring and a second coefficient of thermal expansion of a second material of the heat spreader are different, and wherein in a cross-sectional view a combined structure of the heat spreader and the ring have a H-shaped profile.

### BACKGROUND

Since the development of the integrated circuit (IC), the semiconductor industry has experienced continued rapid growth due to continuous improvements in the integration density of various electronic components (i.e., transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. Other packages have also been developed to incorporate 3D aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 15 are cross-sectional views and top-down views in an example process of forming an integrated circuit package in accordance with some embodiments.

FIGS. 16A and 16B are a cross-sectional view and a top-down view in an example process of forming an integrated circuit package in accordance with some embodiments.

FIGS. 17A and 17B are a cross-sectional view and a top-down view in an example process of forming an integrated circuit package in accordance with some embodiments.

FIGS. 18A and 18B are a cross-sectional view and a top-down view in an example process of forming an integrated circuit package in accordance with some embodiments.

FIGS. 19A through 19C are cross-sectional views and a top-down view in an example process of forming an integrated circuit package in accordance with some embodiments.

FIG. 20 is a cross-sectional view in an example process of forming an integrated circuit package in accordance with some embodiments.

FIGS. 21A and 21B are a cross-sectional view and a top-down view in an example process of forming an integrated circuit package in accordance with some embodiments.

FIG. 22 is a cross-sectional view in an example process of forming an integrated circuit package in accordance with some embodiments.

FIG. 23 is a cross-sectional view in an example process of forming an integrated circuit package in accordance with some embodiments.

FIGS. 24A and 24B are a cross-sectional view and a top-down view in an example process of forming an integrated circuit package in accordance with some embodiments.

FIG. 25 is a cross-sectional view in an example process of forming an integrated circuit package in accordance with some embodiments.

FIG. 26 is a cross-sectional view in an example process of forming an integrated circuit package in accordance with some embodiments.

FIG. 27 is a cross-sectional view in an example process of forming an integrated circuit package in accordance with some embodiments.

FIG. 28 is a cross-sectional view in an example process of forming an integrated circuit package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include integrated circuit packages and methods for forming the same. An integrated circuit package (e.g., a chip-on-wafer-on-substrate (CoWoS) package) includes a package component (e.g., a chip-on-wafer package component comprising one or more semiconductor chips bonded to an interposer) and a package substrate bonded to a side of the interposer opposing the one or more semiconductor chips. A seal adhesive is dispensed on a periphery of the package substrate, and a thermal interface material (TIM) is applied to a top surface of the package component. A lid is subsequently placed on the package substrate, and the lid makes contact with the package substrate by way of the seal adhesive. The lid also makes contact with the package component by way of the TIM. A top portion of the lid that does not overlap the package component includes a plurality of concave portions proximate the perimeter of the package component. Separately, edge portions of the lid that are in contact with the package substrate may comprise concave portions. Advantageous features of such embodiments include reduced expansion and contraction of the lid during subsequent high temperature processes used to securely attach the lid to the package substrate. This may increase the area of a top surface of the package component covered by the TIM, reduce TIM degradation, and increase heat dissipation. As a result, device reliability is improved.

In other embodiments, the integrated circuit package (e.g., a chip-on-wafer-on-substrate (CoWoS) package) includes a package component (e.g., a chip-on-wafer package component comprising at least two semiconductor chips bonded to an interposer) and a package substrate bonded to a side of the interposer opposing the at least two semiconductor chips. An underfill material is dispensed into the gaps between the at least two semiconductor chips, as well as into the gaps between the at least two semiconductor chips and the interposer. A first seal adhesive is dispensed on a periphery of the package substrate, and a ring is attached to the package substrate, wherein the ring surrounds the package component. A second seal adhesive is then dispensed on top surfaces of the ring, and a TIM is applied to a top surface of the package component. A lid is subsequently coupled to the package substrate and the ring, where the lid makes contact with the ring by way of the second seal adhesive. The lid also makes contact with the package component by way of the TIM. The lid and the ring comprise different materials having different coefficients of thermal expansion, and the combined structure of the ring and the lid has a H-shaped cross-sectional profile. Advantageous features of such embodiments include a reduction of stress in the underfill disposed between the at least two semiconductor chips. This results in a reduced risk of delamination between the at least two semiconductor chips and the underfill, which improves device reliability.

Embodiments will be described with respect to a specific context, namely a Die-Interposer-Substrate stacked package using Chip-on-Wafer-on-Substrate (CoWoS) processing. Other embodiments may also be applied, however, to other packages, such as a Die-Die-Substrate stacked package, a System-on-Integrated-Chip (SoIC) package, an Integrated Fan-Out (InFO) package, and other processes.

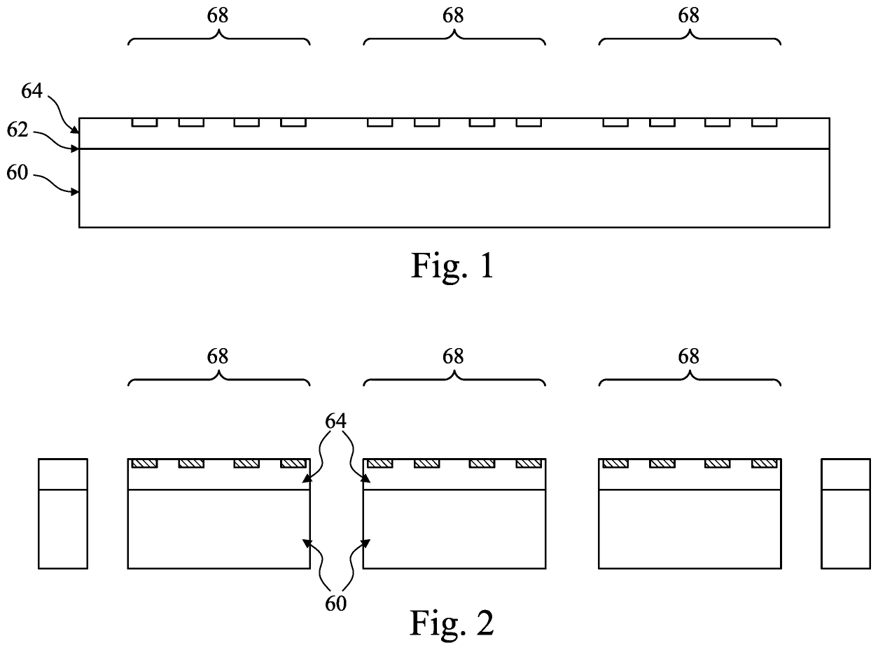

FIGS. 1 through 14B illustrate cross-sectional views of intermediate stages in the manufacturing of an integrated circuit package 10 in accordance with some embodiments. FIG. 1 illustrates one or more dies 68. A main body 60 of the dies 68 may comprise any number of dies, substrates, transistors, active devices, passive devices, or the like. In an embodiment, the main body 60 may include a bulk semiconductor substrate, semiconductor-on-insulator (SOI) substrate, multi-layered semiconductor substrate, or the like. The semiconductor material of the main body 60 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 60 may be doped or undoped. Devices, such as transistors, capacitors, resistors, diodes, and the like, may be formed in and/or on an active surface 62 of the main body 60.

An interconnect structure 64 comprising one or more dielectric layer(s) and respective metallization pattern(s) is formed on the active surface 62. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to form integrated circuits that perform one or more functions. The integrated circuits may include memories, processors, sensors, amplifiers, power distribution devices, input/output circuitry, or the like. Additionally, die connectors, such as conductive pillars (for example, comprising a metal such as copper), are formed in and/or on the interconnect structure 64 to provide an external electrical connection to the circuitry and devices.

As an example to form a layer of the interconnect structure 64, an inter-metallization dielectric (IMD) layer may be formed. The IMD layer may be formed, for example, of a low-K dielectric material, such as phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like, by any suitable method, such as spinning, chemical vapor deposition (CVD), plasma-enhanced CVD (PECVD), high-density plasma chemical vapor deposition (HDP-CVD), or the like. A metallization pattern may be formed in the IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by atomic layer deposition (ALD), or the like. The conductive material of the metallization patterns may comprise copper, aluminum, tungsten, silver, and combinations thereof, or the like, deposited by CVD, physical vapor deposition (PVD), or the like. Any excessive diffusion barrier layer and/or conductive material on the IMD layer may be removed, such as by using a chemical mechanical polish (CMP). Additional layers of the interconnect structure 64 may be formed by repeating these steps.

In FIG. 2, the main body 60 including the interconnect structure 64 is singulated into individual dies 68. Typically, each of the dies 68 contains the same circuitry, such as the same devices and metallization patterns, although some or all of the dies 68 may have different circuitry. The singulation may include sawing, dicing, or the like.

The dies 68 may include logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. Also, in some embodiments, the dies 68 may be different sizes (e.g., different heights and/or surface areas), and in other embodiments, the dies 68 may be the same size (e.g., same heights and/or surface areas).

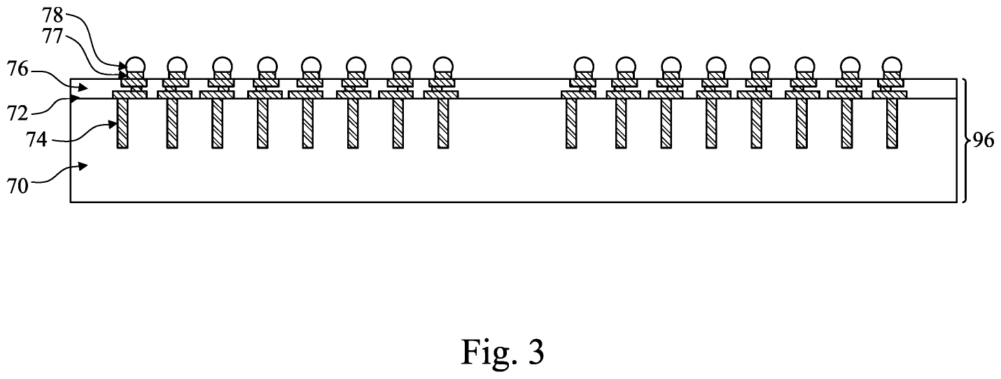

FIG. 3 illustrates one or more components 96 during processing. The components 96 may be interposers or other dies. A substrate 70 may form the main body of the components 96. The substrate 70 can be a wafer. The substrate 70 may comprise a bulk semiconductor substrate, SOI substrate, multi-layered semiconductor substrate, or the like. The semiconductor material of the substrate 70 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 70 may be doped or undoped. Devices, such as transistors, capacitors, resistors, diodes, and the like, may (or may not) be formed in and/or on a first surface 72, which may also be referred to as an active surface, of the substrate 70. In embodiments where the components 96 are interposers, the components 96 will generally not include active devices therein, although the interposer may include passive devices formed in and/or on a first surface 72. In such embodiments, the components 96 may be free of any active devices on the substrate 70.

Through-vias (TVs) 74 are formed to extend from the first surface 72 of the substrate 70 into the substrate 70. The TVs 74 are also sometimes referred to as through-substrate vias, or through-silicon vias when substrate 70 is a silicon substrate. The TVs 74 may be formed by forming recesses in the substrate 70 by, for example, etching, milling, laser techniques, a combination thereof, and/or the like. A thin barrier layer may be conformally deposited over the front side of the substrate 70 and in the recesses, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the recesses. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 70 by, for example, CMP. Thus, the TVs 74 may comprise a conductive material and a thin barrier layer between the conductive material and the substrate 70.

Interconnect structure 76 is formed over the first surface 72 of the substrate 70, and is used to electrically connect the integrated circuit devices, if any, and/or TVs 74 together and/or to external devices. The interconnect structure 76 may include one or more dielectric layer(s) and respective metallization pattern(s) in the dielectric layer(s). The metallization patterns may comprise vias and/or traces to interconnect any devices and/or TVs 74 together and/or to an external device. The dielectric layers may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layers may be deposited by any suitable method, such as spinning, CVD, PECVD, HDP-CVD, or the like. A metallization pattern may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVC, or the like. Any excessive diffusion barrier layer and/or conductive material on the dielectric layer may be removed, such as by using a CMP.

Electrical connectors 77/78 are formed at the top surface of the interconnect structure 76 on conductive pads that are formed in the dielectric layers of the interconnect structure 76. In some embodiments, the electrical connectors 77/78 include metal pillars 77 with metal cap layers 78, which may be solder caps, over the metal pillars 77. The electrical connectors 77/78 (including the pillars 77 and the cap layers 78) are sometimes referred to as micro bumps 77/78. In some embodiments, the metal pillars 77 include a conductive material such as copper, aluminum, gold, nickel, palladium, the like, or a combination thereof and may be formed by sputtering, printing, electro plating, electroless plating, CVD, or the like. The metal pillars 77 may be solder-free and have substantially vertical sidewalls. In some embodiments, respective metal cap layers 78 are formed on the respective top surfaces of the metal pillars 77. The metal cap layers 78 may include nickel, tin, tin-lead, gold, copper, silver, palladium, indium, nickel-palladium-gold, nickel-gold, the like, or a combination thereof and may be formed by a plating process.

In another embodiment, the electrical connectors 77/78 do not include the metal pillars and are solder balls and/or bumps, such as controlled collapse chip connection (C4), electroless nickel immersion Gold (ENIG), electroless nickel electroless palladium immersion gold technique (ENEPIG) formed bumps, or the like. In such embodiments, the bump electrical connectors 77/78 may include a conductive material such as solder, copper, aluminum, gold, nickel, silver, palladium, tin, the like, or a combination thereof. The electrical connectors 77/78 may be formed by initially forming a layer of solder through methods such as evaporation, electroplating, printing, solder transfer, ball placement, or the like. Once a layer of solder has been formed on the structure, a reflow may be performed in order to shape the material into the desired bump shapes.

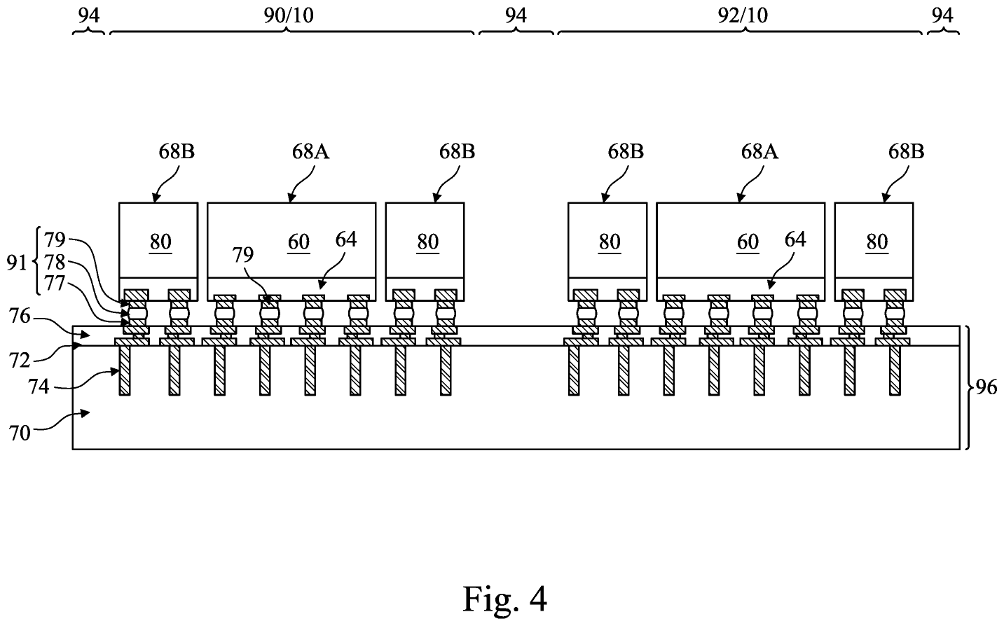

In FIG. 4, dies 68 (including dies 68A and dies 68B) are attached to the first side of the components 96, for example, through flip-chip bonding by way of the electrical connectors 77/78 and metal pillars 79 on the dies to form conductive joints 91. The metal pillars 79 may be similar to the metal pillars 77 and their description is not repeated herein. The dies 68 may be placed on the electrical connectors 77/78 using, for example, a pick-and-place tool. In some embodiments, the metal cap layers 78 are formed on the metal pillars 77 (as shown in FIG. 3), the metal pillars 79 of the dies 68, or both.

The dies 68A and the dies 68B may be different types of dies. In some embodiments, the dies 68A include logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. In some embodiments, the dies 68A are system-on-a-chip (SoC) or graphics processing units (GPUs) and the dies 68B are memory dies that are utilized by the dies 68A.

In some embodiments, the dies 68B include one or more memory dies, such as a stack of memory dies (e.g., DRAM dies, SRAM dies, High-Bandwidth Memory (HBM) dies, Hybrid Memory Cubes (HMC) dies, or the like). In the embodiments utilizing a stack of memory dies, a die 68B can include both memory dies and a memory controller, such as, for example, a stack of four or eight memory dies with a memory controller. Also, in some embodiments, the dies 68B may be different sizes (e.g., different heights and/or surface areas) from the dies 68A, and in other embodiments, the dies 68B may be the same size (e.g., same heights and/or surface areas) as the dies 68A. In some embodiments, the dies 68B may be similar heights to those of the dies 68A (as shown in FIG. 4) or in some embodiments, the dies 68A and 68B may be of different heights.

The conductive joints 91 electrically couple the circuits in the dies 68, through the interconnect structures 64, to the interconnect structure 76 and the TVs 74 of the components 96. Additionally, the interconnect structure 76 electrically interconnects the dies 68A and the dies 68B to each other.

In some embodiments, before bonding the electrical connectors 77/78, the electrical connectors 77/78 are coated with a flux (not shown), such as a no-clean flux. The electrical connectors 77/78 may be dipped in the flux or the flux may be jetted onto the electrical connectors 77/78. In another embodiment, the flux may also be applied to the electrical connectors 79/78. In some embodiments, the electrical connectors 77/78 and/or 79/78 may have an epoxy flux (not shown) formed thereon before they are reflowed, with at least some of the epoxy portion of the epoxy flux remaining after the dies 68 are attached to the components 96. This remaining epoxy portion may act as an underfill to reduce stress and protect the joints resulting from the reflowing the electrical connectors 77/78/79.

The bonding between the dies 68 and the components 96 may be a solder bonding or a direct metal-to-metal (such as a copper-to-copper or tin-to-tin) bonding. In an embodiment, the dies 68 are bonded to the components 96 by a reflow process. During this reflow process, the electrical connectors 77/78/79 are in contact to physically and electrically couple the dies 68 to the components 96. After the bonding process, an IMC (not shown) may form at the interface of the metal pillars 77/79 and the metal cap layers 78.

In FIG. 4 and subsequent figures, a first package region 90 and a second package region 92 for the formation of a first integrated circuit package and a second integrated circuit package, respectively, are illustrated. Scribe line regions 94 are between adjacent package regions. As illustrated in FIG. 4, a single die 68A and multiple dies 68B are attached in each of the first package region 90 and the second package region 92.

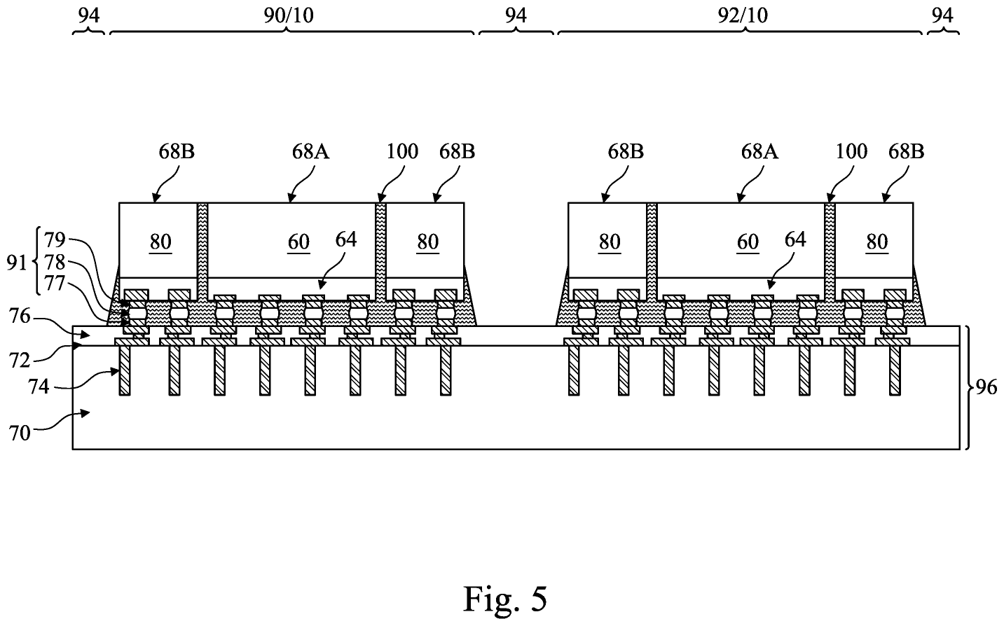

In FIG. 5, an underfill material 100 is dispensed into the gaps between the dies 68 and the interconnect structure 76. In addition, the underfill material may be dispensed into the gaps between sidewalls of adjacent dies 68. The underfill material 100 extends up along sidewall of the dies 68A and the dies 68B. The underfill material 100 may be any acceptable material, such as a polymer, epoxy, molding underfill, or the like. The underfill material 100 may be formed by a capillary flow process after the dies 68 are attached, or may be formed by a suitable deposition method before the dies 68 are attached.

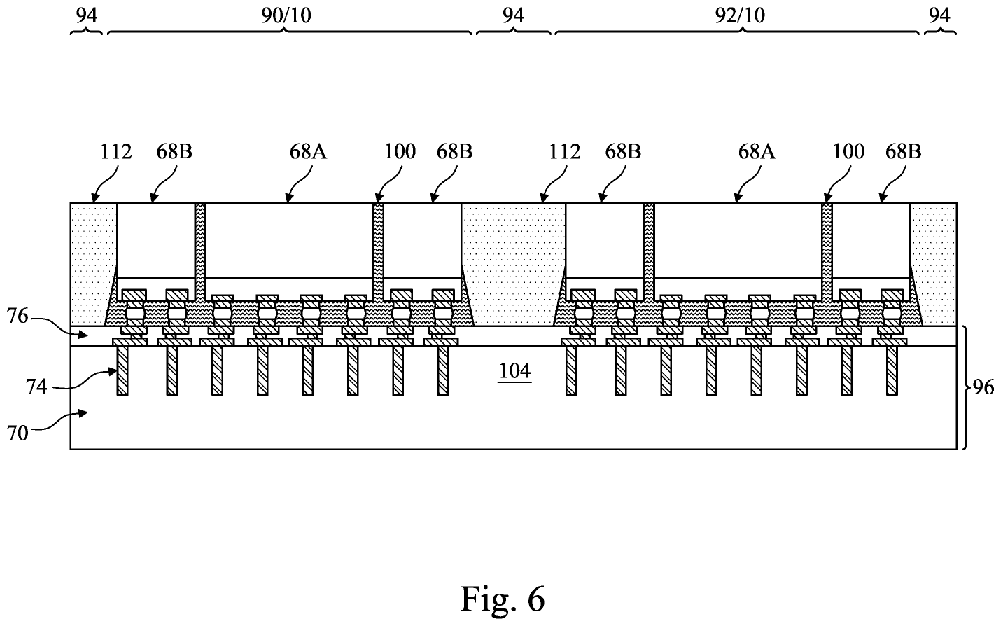

In FIG. 6, an encapsulant 112 is formed on the various components. The encapsulant 112 may be a molding compound, epoxy, or the like, and may be applied by compression molding, transfer molding, or the like. A curing step is performed to cure the encapsulant 112, such as a thermal curing, an Ultra-Violet (UV) curing, or the like. In some embodiments, the dies 68 are buried in the encapsulant 112, and after the curing of the encapsulant 112, a planarization step, such as a grinding, may be performed to remove excess portions of the encapsulant 112, which excess portions are over top surfaces of the dies 68. Accordingly, top surfaces of dies 68 are exposed, and are level with a top surface of the encapsulant 112. In some embodiments, the dies 68B may be different heights from the dies 68A, and the dies 68B are still covered by the encapsulant 112 after the planarization step.

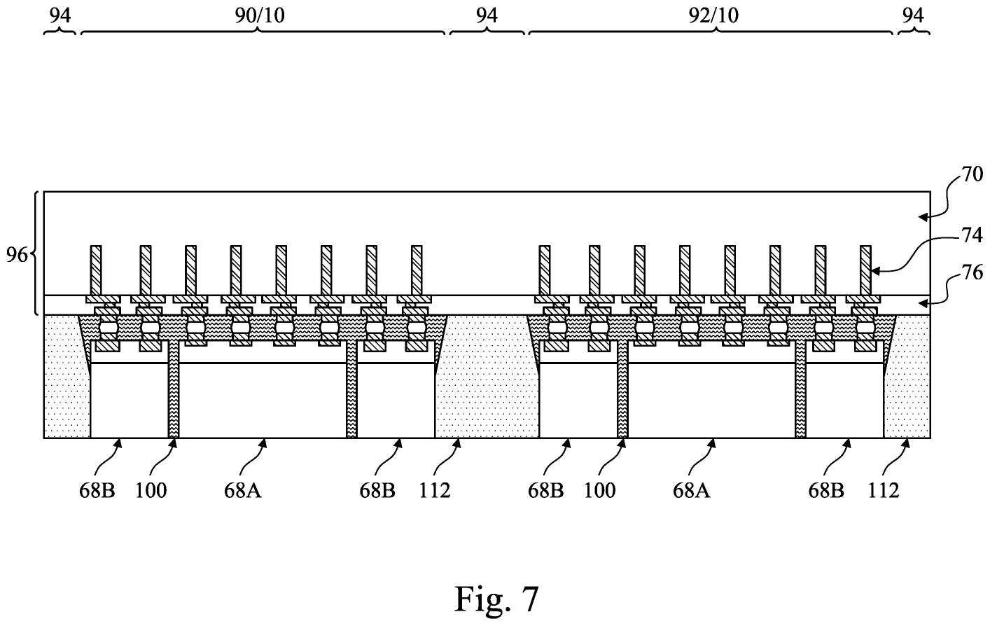

FIGS. 7 through 10 illustrate processing of the second side of components 96. In FIG. 7, the structure of FIG. 6 is flipped over to prepare for the formation of the second side of components 96. Although not shown, the structure may be placed on carrier or support structure for the process of FIGS. 7 through 10.

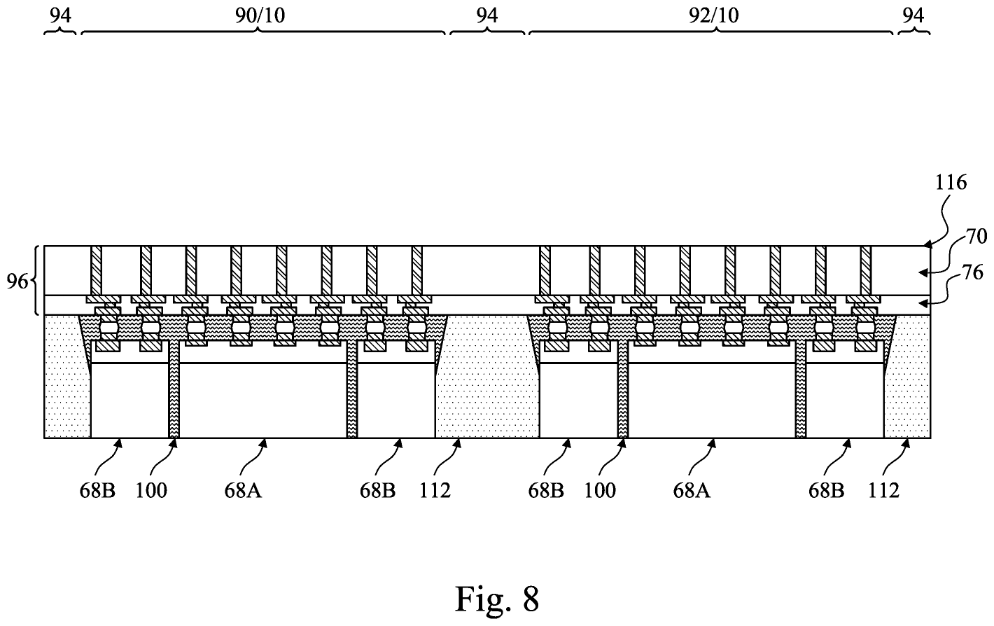

In FIG. 8, a thinning process is performed on the second side of the substrate 70 to thin the substrate 70 until TVs 74 are exposed. The thinning process may include an etching process, a grinding process, the like, or a combination thereof, applied to a second surface 116 of the substrate 70.

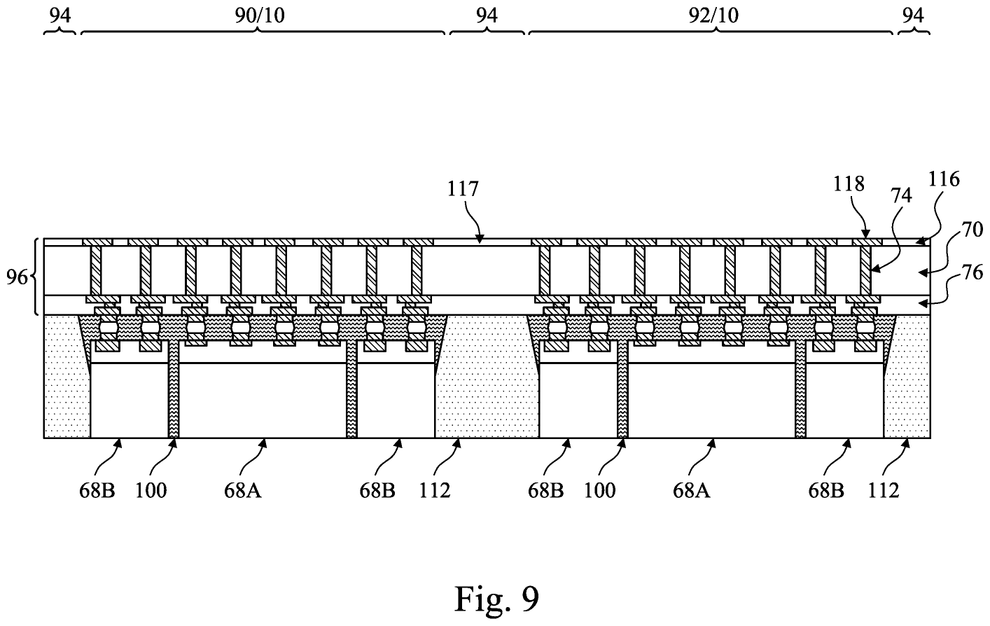

In FIG. 9, a redistribution structure is formed on the second surface 116 of the substrate 70, and will be used to electrically connect the TVs 74 to external devices. The redistribution structure includes a dielectric layer 117 and metallization patterns 118 in and/or on the dielectric layer 117. The metallization patterns may comprise vias and/or traces to interconnect TVs 74 together and/or to an external device. The metallization patterns 118 are sometimes referred to as Redistribution Lines (RDLs). The dielectric layer 117 may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layer 117 may be deposited by any suitable method, such as spinning, CVD, PECVD, HDP-CVD, or the like. The metallization patterns 118 may be formed in the dielectric layer 117, for example, by using photolithography techniques to deposit and pattern a photoresist material on the dielectric layer 117 to expose portions of the dielectric layer 117 that are to become the metallization pattern 118. An etch process, such as an anisotropic dry etch process, may be used to create openings in the dielectric layer 117 corresponding to the exposed portions of the dielectric layer 117. A seed layer (not separately illustrated) is formed over the exposed surfaces of the dielectric layer 117 and in the openings. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization patterns 118. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the metallization patterns 118.

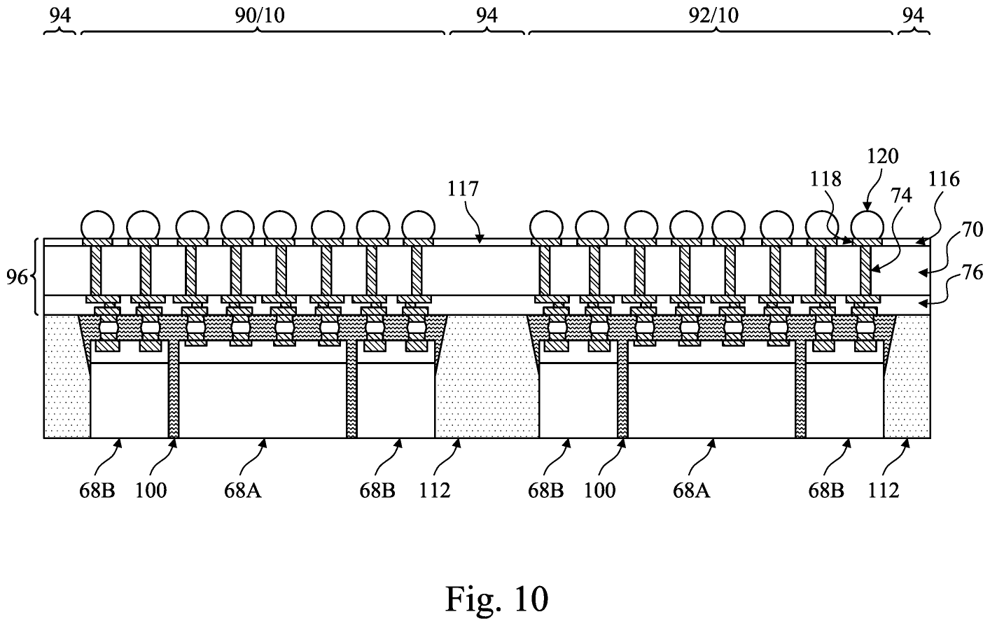

In FIG. 10, electrical connectors 120 are formed the metallization patterns 118 and are electrically coupled to TVs 74. The electrical connectors 120 are formed at the top surface of the redistribution structure on the metallization patterns 118. In some embodiments, the metallization patterns 118 include UBMs. The electrical connectors 120 can be formed on the UBMs.

In some embodiments, the electrical connectors 120 are solder balls and/or bumps, such as ball grid array (BGA) balls, C4 micro bumps, ENIG formed bumps, ENEPIG formed bumps, or the like. The electrical connectors 120 may include a conductive material such as solder, copper, aluminum, gold, nickel, silver, palladium, tin, the like, or a combination thereof. In some embodiments, the electrical connectors 120 are formed by initially forming a layer of solder through methods such as evaporation, electroplating, printing, solder transfer, ball placement, or the like. Once a layer of solder has been formed on the structure, a reflow may be performed in order to shape the material into the desired bump shapes. In another embodiment, the electrical connectors 120 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 120. The metal cap layer may include nickel, tin, tin-lead, gold, silver, palladium, indium, nickel-palladium-gold, nickel-gold, the like, or a combination thereof and may be formed by a plating process.

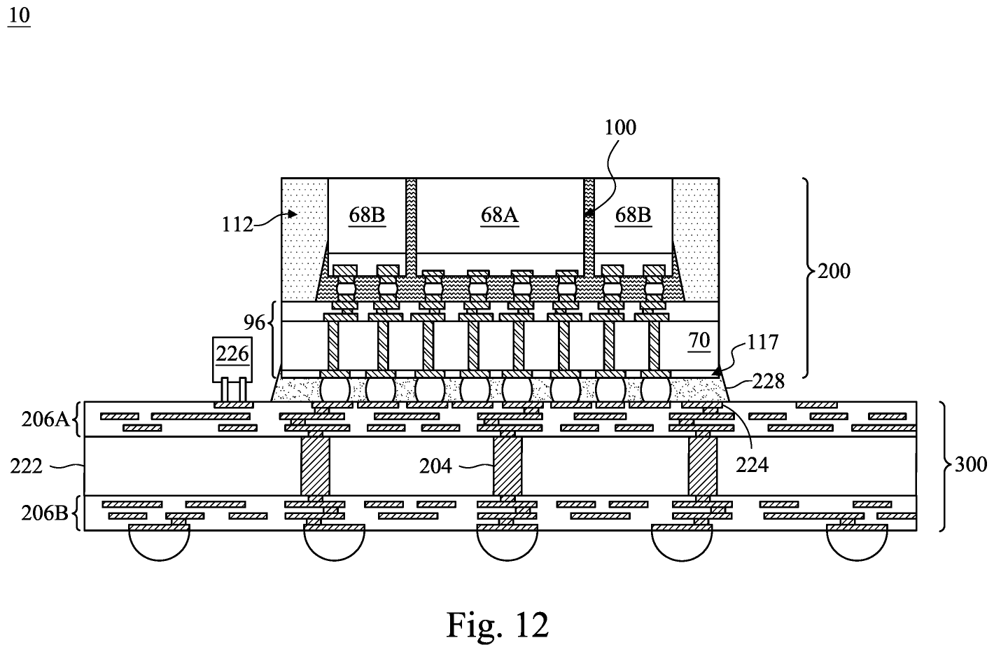

The electrical connectors 120 will be used to bond to an additional electrical component, which may be a semiconductor substrate, a package substrate, a Printed Circuit Board (PCB), or the like (see FIG. 12).

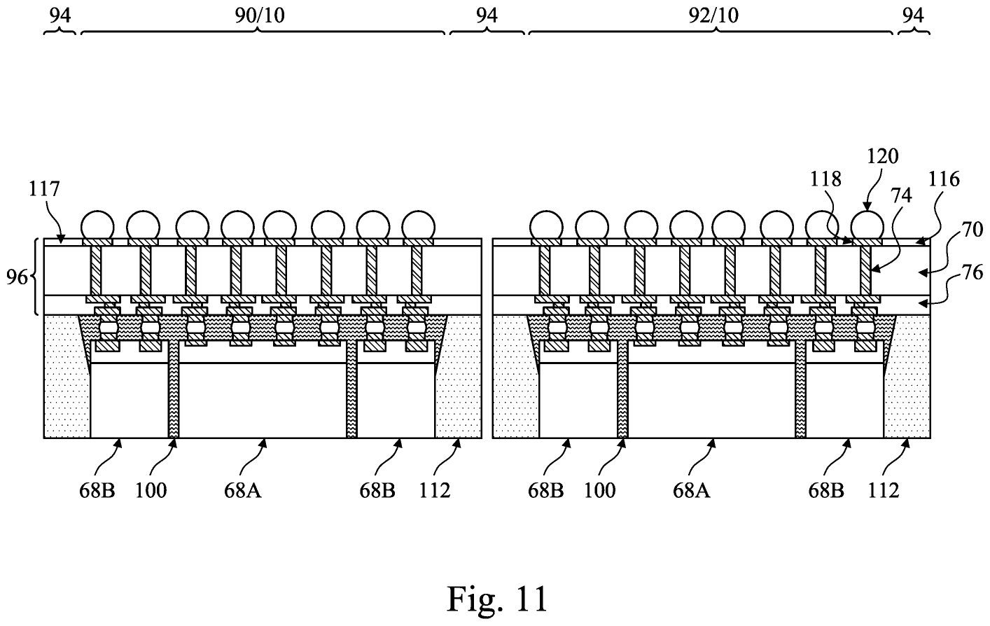

In FIG. 11, components 96 are singulated between adjacent regions 90 and 92 along scribe line regions 94 to form package components 200 comprising, among other things, a die 68A, a component 96, and dies 68B. The singulation may be by sawing, dicing, or the like.

FIG. 12 illustrates the attachment of a package component 200 on a substrate 300. Electrical connectors 120 are aligned to, and are put against, bond pads 224 of the substrate 300. The electrical connectors 120 may be reflowed to bond the substrate 300 to the component 96.

The substrate 300 may comprise, for example, an organic substrate, a ceramic substrate, a silicon substrate, or the like. The substrate 300 may comprise electrical connectors, such as solder balls, opposite the package component 200 to allow the substrate 300 to be mounted to another device.

Before being attached to the package component 200, the substrate 300 may be processed according to applicable manufacturing processes to form redistribution structures in the substrate 300. For example, the substrate 300 includes a substrate core 222. The substrate core 222 may be formed of glass fiber, resin, filler, other materials, and/or combinations thereof. The substrate core 222 may be formed of organic and/or inorganic materials. In some embodiments, the substrate core 222 includes one or more passive components (not shown) embedded inside. Alternatively, the substrate core 222 may comprise other materials or components. Conductive vias 204 are formed extending through the substrate core 222. The conductive vias 204 comprise a conductive material such as copper, a copper alloy, or other conductors, and may include a barrier layer, liner, seed layer, and/or a fill material, in some embodiments. The conductive vias 204 provide vertical electrical connections from one side of the substrate core 222 to the other side of the substrate core 222. For example, some of the conductive vias 204 are coupled between conductive features at one side of the substrate core 222 and conductive features at an opposite side of the substrate core 222. Holes for the conductive vias 204 may be formed using a drilling process, photolithography techniques, a laser process, or other methods, as examples, and the holes of the conductive vias 204 are then filled with conductive material. In some embodiments, the conductive vias 204 are hollow conductive through vias having centers that are filled with an insulating material. Redistribution structures 206A and 206B are formed on opposing sides of the substrate core 222. The redistribution structures 206A and 206B are electrically coupled by the conductive vias 204, and may fan-out electrical signals. The redistribution structures 206A and 206B each include dielectric layers and metallization patterns. The redistribution structure 206A is attached to the package component 200 by the electrical connectors 120.

An underfill material 228 can be dispensed between the package component 200 and the substrate 300 and surrounding the electrical connectors 120. The underfill material 228 may be any acceptable material, such as a polymer, epoxy, molding underfill, or the like.

Additionally, one or more surface devices 226 may be connected to the substrate 300. The surface devices 226 may be used to provide additional functionality or programming to the package component 200, or the package as a whole. In an embodiment, the surface devices 226 may include surface mount devices (SMDs) or integrated passive devices (IPDs) that include passive devices such as resistors, inductors, capacitors, jumpers, combinations of these, or the like that are desired to be connected to and utilized in conjunction with package component 200, or other parts of the integrated circuit package 10. The surface devices 226 may be placed on a first major surface of the substrate 300, an opposing major surface of the substrate 300, or both, according to various embodiments.

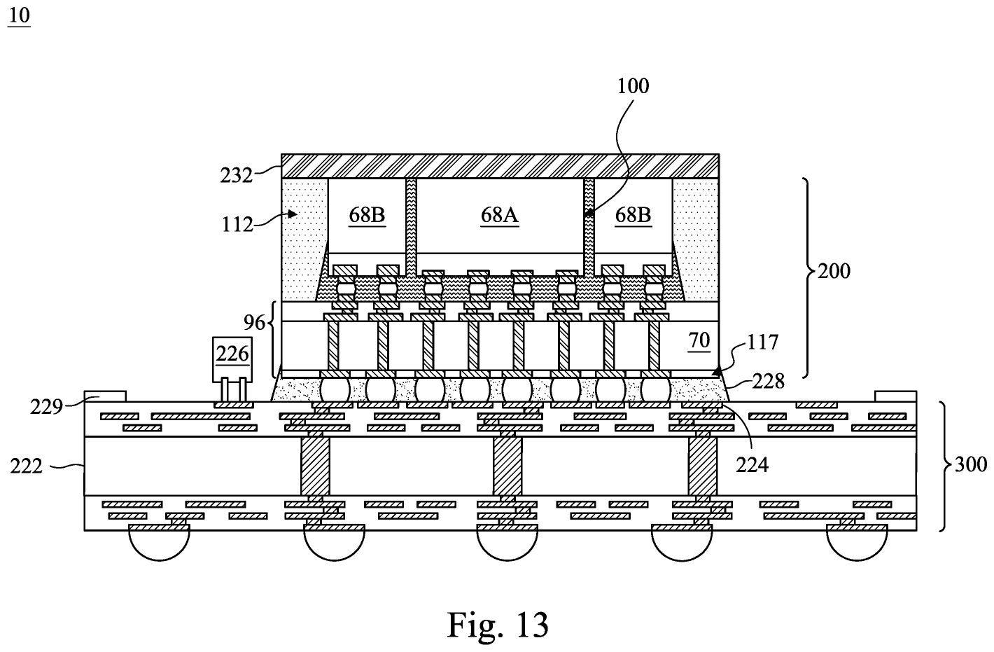

In FIG. 13, an adhesive material 229 is dispensed on the substrate 300. The adhesive material 229 may comprise any material suitable for sealing a component such as a ring or a heat spreader (e.g., a thermal lid or thermal ring) onto the substrate 300, such as epoxies, urethane, polyurethane, silicone elastomers, and the like. The adhesive material 229 may be dispensed to an outer portion or a periphery of the substrate 300, such that the adhesive material 229 is between the package component 200 and the edges of the substrate 300. Additionally, a thermal interface material (TIM) 232 is applied to the top of the package component 200. The TIM 232 is formed of a thermally conductive material. Acceptable thermally conductive materials include thermal grease; a phase change material; a metal filled polymer matrix; solder alloys of lead, tin, indium, silver, copper, bismuth, and the like (such as indium or lead/tin alloy); or the like. If the TIM 232 is a solid material, it may be heated to a temperature at which it undergoes a solid to liquid transition and then may be applied in liquid form to the top surface of the package component 200.

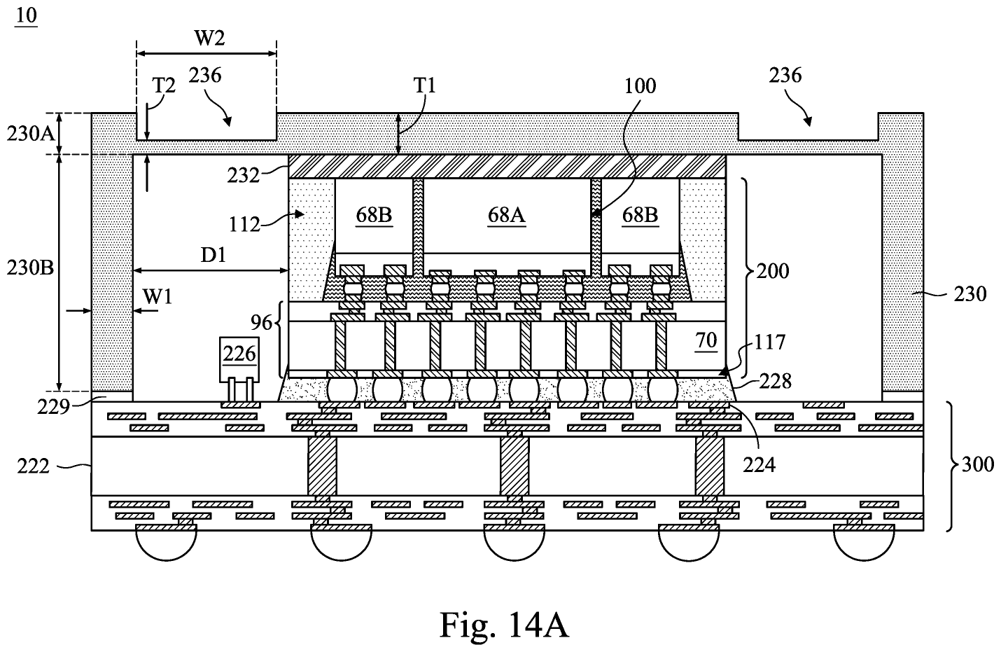

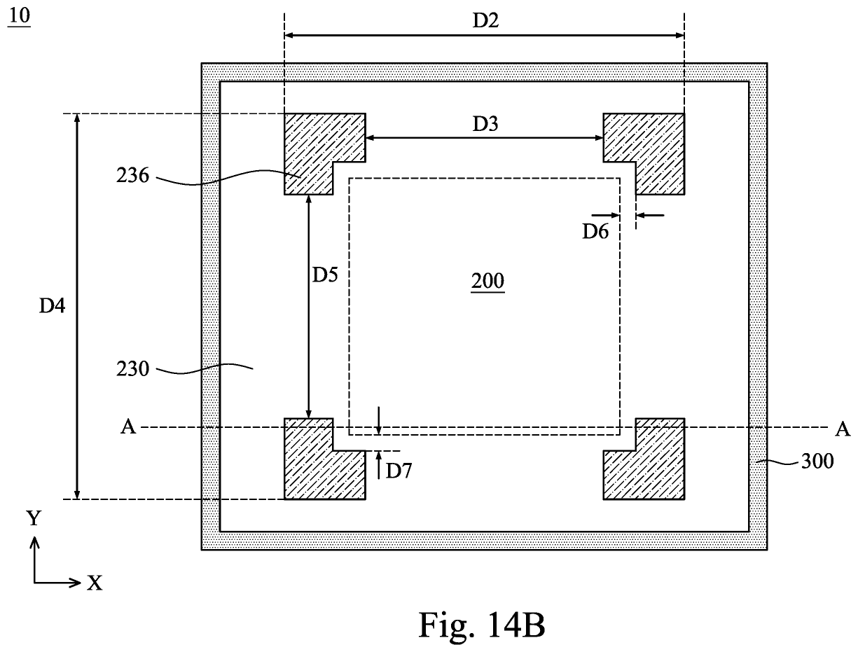

FIGS. 14A and 14B illustrate the placing of a heat spreader 230 on the substrate 300. FIG. 14A illustrates a cross-sectional view of the integrated circuit package 10 along the line A-A shown in FIG. 14B. FIG. 14B illustrates a top-down view of the integrated circuit package 10 after the placing of the heat spreader 230 on the substrate 300. The heat spreader 230 may be a thermal lid, a thermal ring, or the like. A recess is in the bottom of the thermal lid or thermal ring so that the thermal lid or thermal ring can cover the package component 200. In some embodiments where the heat spreader 230 is a thermal lid or thermal ring, the thermal lid or thermal ring can also cover the surface devices 226. The heat spreader 230 may be formed of a material with high thermal conductivity, such as a metal, such as copper, steel, iron, or the like. The heat spreader 230 protects the package component 200 and forms a thermal pathway to conduct heat from the various components of the package component 200 (e.g., the dies 68). The heat spreader 230 is thermally coupled to the back-side surface of the package component 200 through the TIM 232, and coupled to the substrate 300 through the adhesive material 229.

The heat spreader 230 comprises a top portion 230A and a bottom portion 230B below the top portion 230A. In an embodiment, the top portion 230A and the bottom portion 230B comprise the same continuous material. In an embodiment, the top portion 230A and the bottom portion 230B comprise different materials. The top portion 230A is above and in physical contact with a top surface of the package component 200 by way of the TIM 232. The bottom portion 230B is in physical contact with the substrate 300 by way of the adhesive material 229. The bottom portion 230B surrounds the package component 200. As illustrated in FIG. 14A, the top portion 230A of the heat spreader 230 comprises a top surface having a plurality of concave portions 236 that are disposed between each sidewall of the package component 200 and nearest respective inner sidewall of the bottom portion 230B. The plurality of concave portions 236 may comprise recesses in the top surface of the top portion 230A. The plurality of concave portions 236 may also be referred to subsequently as a plurality of grooved portions or a plurality of recessed portions. In another embodiment (not separately illustrated), the plurality of concave portions 236 may overlap the bottom portion 230B. In an embodiment, at a point adjacent the plurality of concave portions 236, the top portion 230A may have a maximum thickness T1 in the range from 1.5 mm to 3.5 mm. In an embodiment, at a point beneath the plurality of concave portions 236, the top portion 230A may have a smallest thickness T2 in a range from 0.5 mm to 1.5 mm. As illustrated in FIG. 14B, the plurality of concave portions 236 may be proximate the perimeter of the package component 200 (e.g., at the corners of the package component 200), such that the plurality of concave portions 236 do not overlap the package component 200 in the top-down view. In an embodiment, each of the plurality of concave portions 236 may comprise an L-shape in a top-down view (as further illustrated in FIG. 14B) proximate a respective corner of the package component 200.

In an embodiment, the bottom portion 230B may have a width W1 that is in a range from 2 mm to 5 mm. In an embodiment, each of the plurality of concave portions 236 may have a width W2 (as seen in FIG. 14A) that is in a range from 3 mm to 5 mm. In an embodiment, a distance D1 between a first sidewall of the package component 200 and a nearest inner sidewall of the bottom portion 230B may be in a range from 3 mm to 5 mm. The width W2 may be larger, smaller, or equal to the distance D1. The width W1 may be larger, smaller, or equal to the width W2. In an embodiment, a distance D2 in a first direction (e.g., the x-direction) between a first outer sidewall of a first of the plurality of concave portions 236 and a second outer sidewall of an adjacent second of the plurality of concave portions 236 is in a range from 40 mm to 80 mm, wherein the first outer sidewall is the furthest sidewall of the first of the plurality of concave portions 236 from the package component 200 in the first direction, wherein the second outer sidewall is the furthest sidewall of the second of the plurality of concave portions 236 from the package component 200 in the first direction, and wherein the first of the plurality of concave portions 236 is proximate a first corner of the package component 200 and the second of the plurality of concave portions 236 is proximate a second corner of the package component 200. In an embodiment, a distance D3 in the first direction between inner sidewalls of the first of the plurality of concave portions 236 and the second of the plurality of concave portions 236 is in a range from 20 mm to 40 mm. In an embodiment, the distance D3 is less than D2. In an embodiment, a ratio of the distance D3 to the distance D2 is in the range of 0.1 and 0.99. In an embodiment, a distance D4 in a second direction (e.g., the y-direction) between a third outer sidewall of the first of the plurality of concave portions 236 and a fourth outer sidewall of an adjacent third of the plurality of concave portions 236 is in a range from 40 mm to 80 mm, wherein the third outer sidewall is the furthest sidewall of the first of the plurality of concave portions 236 from the package component 200 in the second direction, wherein the fourth outer sidewall is the furthest sidewall of the third of the plurality of concave portions 236 from the package component 200 in the second direction, and wherein the third of the plurality of concave portions 236 is proximate a third corner of the package component 200. In an embodiment, a distance D5 in the second direction between inner sidewalls of the first of the plurality of concave portions 236 and the third of the plurality of concave portions 236 is in a range from 20 mm to 40 mm. In an embodiment, the distance D5 is less than the distance D4. In an embodiment, a ratio of the distance D5 to the distance D4 is in the range of 0.1 and 0.99. The distance D2 may be smaller, larger, or equal to the distance D4. In an embodiment, a distance D6 in the first direction between a sidewall of the package component 200 and an inner sidewall of the second of the plurality of concave portions 236 is in a range from 0 mm to 3 mm. In an embodiment, a distance D7 in the second direction between a sidewall of the package component 200 and an inner sidewall of the third of the plurality of concave portions 236 is in a range from 0 mm to 3 mm. The distance D6 is smaller than the distance D3. In an embodiment, the distance D6 is greater than 0.2 mm. The distance D7 is smaller than the distance D5. In an embodiment, the distance D7 is greater than 0.2 mm.

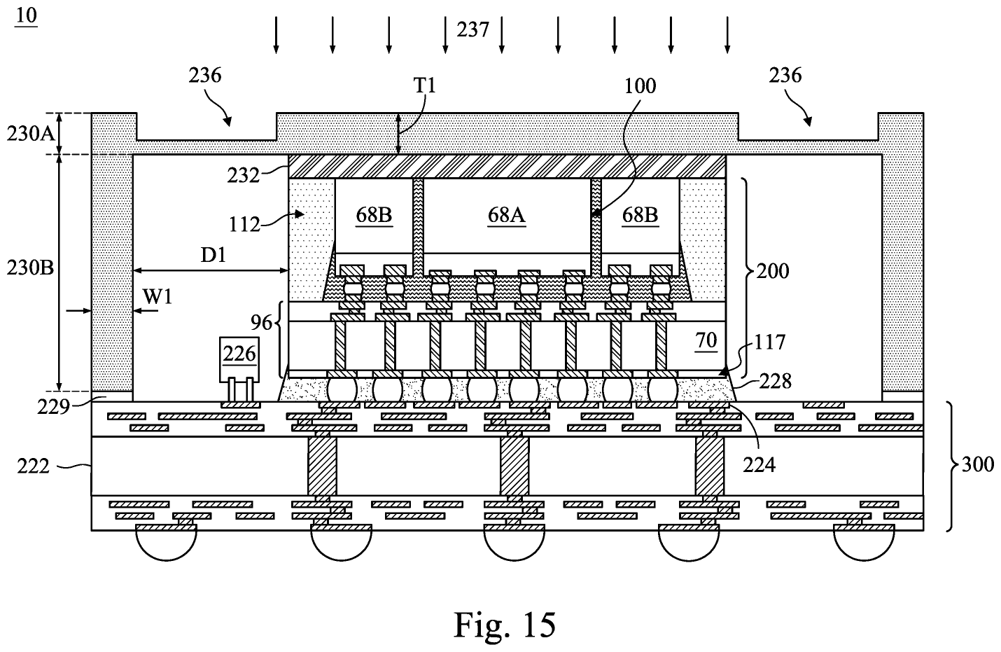

In FIG. 15, a process 237 is performed in which heat and pressure is applied to a top surface of the heat spreader 230 and a bottom surface of the substrate 300 in order to press and hold the heat spreader 230 to the substrate 300 in a fixed position such that movement of the heat spreader 230 relative to the substrate 300 is restricted. During the process 237, the TIM 232 may undergo a solid to liquid transition that aids in increased coverage of the TIM 232 over the top surface of the package component 200. After the process 237 is performed, a suitable curing process may then be performed to cure the adhesive material 229 to enable secure attachment of the heat spreader 230 to the substrate 300.

Advantages may be achieved as a result of the top portion 230A of the heat spreader comprising the plurality of concave portions 236 disposed between each sidewall of the package component 200 and nearest respective inner sidewall of the bottom portion 230B of the heat spreader 230, such that each of the plurality of concave portions 236 comprises an L-shape in a top-down view, and is proximate a respective corner of the package component 200. These advantages include reduced expansion and contraction of the heat spreader 230 during and after the process 237, as a result of the heat spreader 230 having less volume. This may increase the area of a top surface of the package component covered by the TIM, reduce TIM degradation, and increase heat dissipation. As a result, device reliability is improved.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

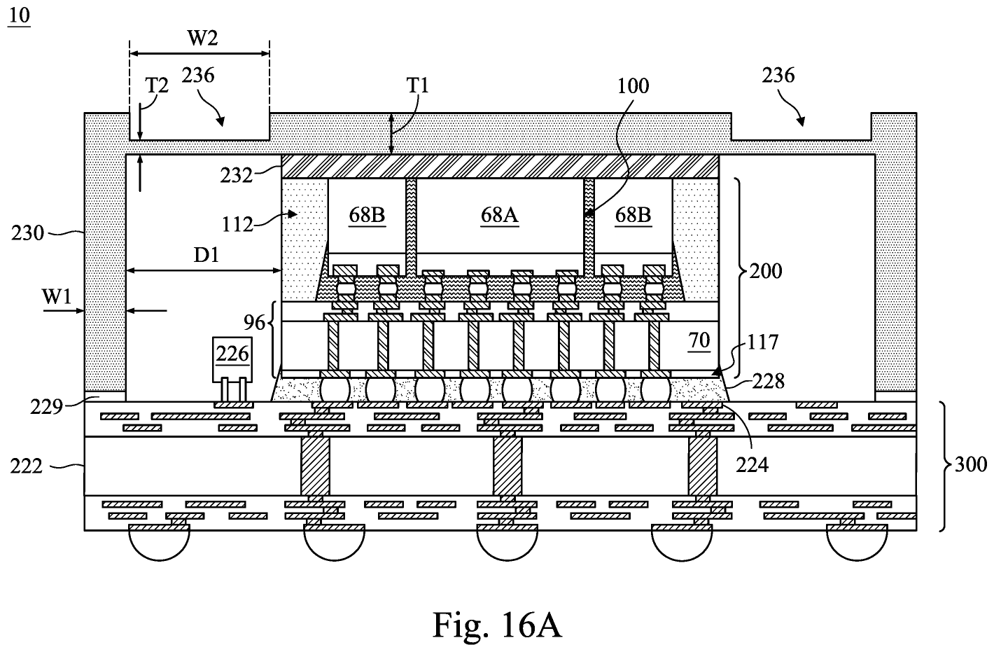

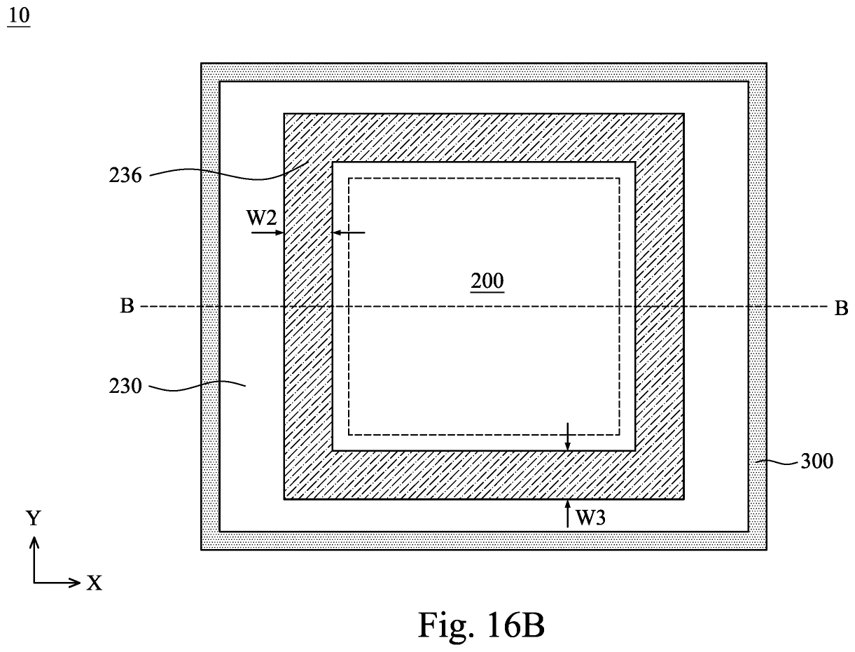

FIGS. 16A and 16B illustrate the integrated circuit package 10 in accordance with some other embodiments. FIG. 16A illustrates a cross-sectional view of the integrated circuit package 10 along the line B-B shown in FIG. 16B. FIG. 16B illustrates a top-down view of the integrated circuit package 10.

As illustrated in FIG. 16A, the top portion 230A of the heat spreader 230 comprises a top surface having a single concave portion 236. The concave portion 236 is a groove that extends around the package component 200 in the top-down view, and is disposed between each sidewall of the package component 200 and a nearest respective inner sidewall of the bottom portion 230B. The concave portion 236 may also be referred to subsequently as a grooved portion or a recessed portion. In another embodiment (not separately illustrated), the concave portion 236 may overlap the bottom portion 230B. As illustrated in FIG. 16B, the concave portion 236 may be proximate the perimeter of the package component 200, (e.g., surrounding an entire perimeter of the package component 200) wherein the concave portion 236 does not overlap the package component 200. In an embodiment, the concave portion 236 may comprise a width W2 in the first direction (e.g., the x-direction) that is in a range from 3 mm to 5 mm. In an embodiment, the concave portion 236 may comprise a width W3 in the second direction (e.g., the y-direction) that is in a range from 3 mm to 5 mm. The width W2 may be smaller, larger, or equal to the width W3.

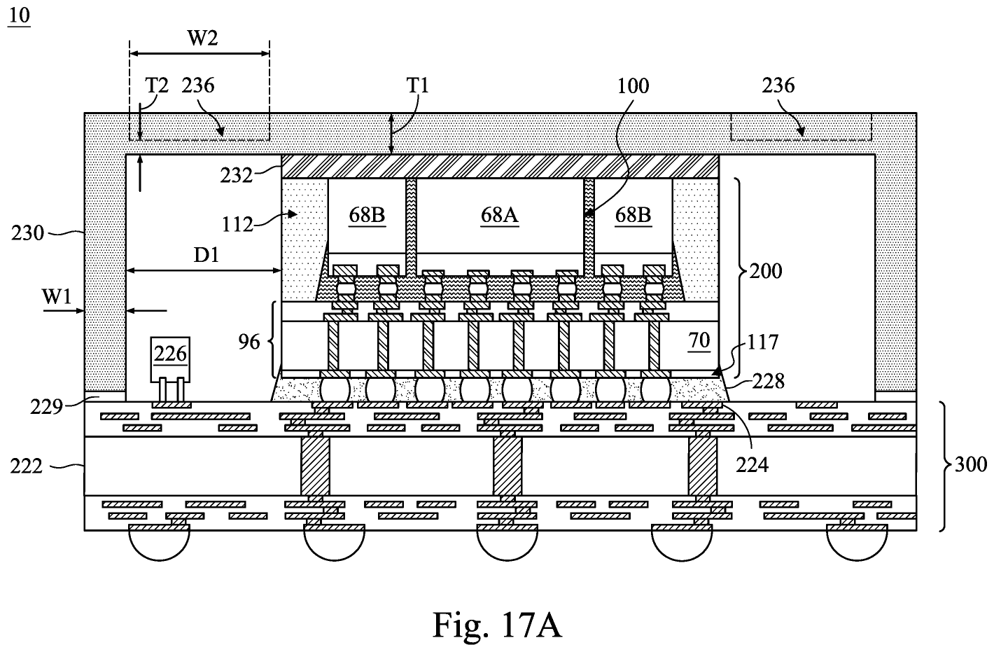

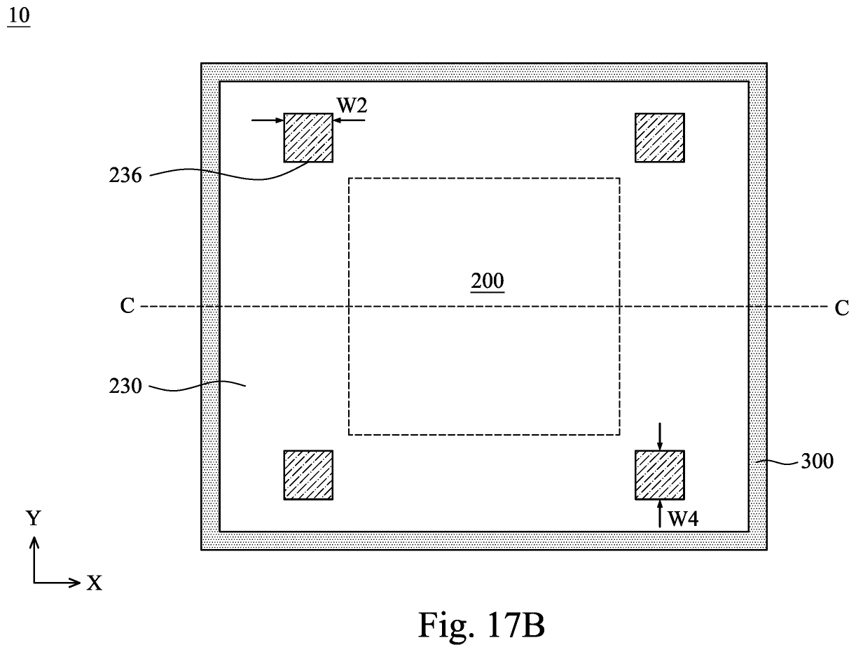

FIGS. 17A and 17B illustrate the integrated circuit package 10 in accordance with some other embodiments. FIG. 17A illustrates a cross-sectional view of the integrated circuit package 10 along the line C-C shown in FIG. 17B. FIG. 17B illustrates a top-down view of the integrated circuit package 10.

As illustrated in FIG. 17A, the top portion 230A of the heat spreader 230 comprises a top surface having a plurality of concave portions 236 that are disposed between each sidewall of the package component 200 and nearest respective inner sidewall of the bottom portion 230B. The location of the plurality of concave portions 236 are shown in ghost. The plurality of concave portions 236 may also be referred to subsequently as a plurality of grooved portions or a plurality of recessed portions. In another embodiment (not separately illustrated), the plurality of concave portions 236 may overlap the bottom portion 230B. As illustrated in FIG. 17B, the plurality of concave portions 236 are proximate the perimeter of the package component 200 (e.g., at the corners of the package component 200), such that the plurality of concave portions 236 do not overlap the package component 200. In an embodiment, each of the plurality of concave portions 236 may comprise a square or rectangle shape in a top-down view (as further illustrated in FIG. 16B) proximate a respective corner of the package component 200. In an embodiment, each of the plurality of concave portions 236 may comprise the width W2 in the first direction (e.g., the x-direction) that is in a range from 3 mm to 5 mm. In an embodiment, each of the plurality of concave portions 236 may comprise a width W4 in the second direction (e.g., the y-direction) that is in a range from 3 mm to 5 mm. The width W2 may be smaller, larger, or equal to the width W4.

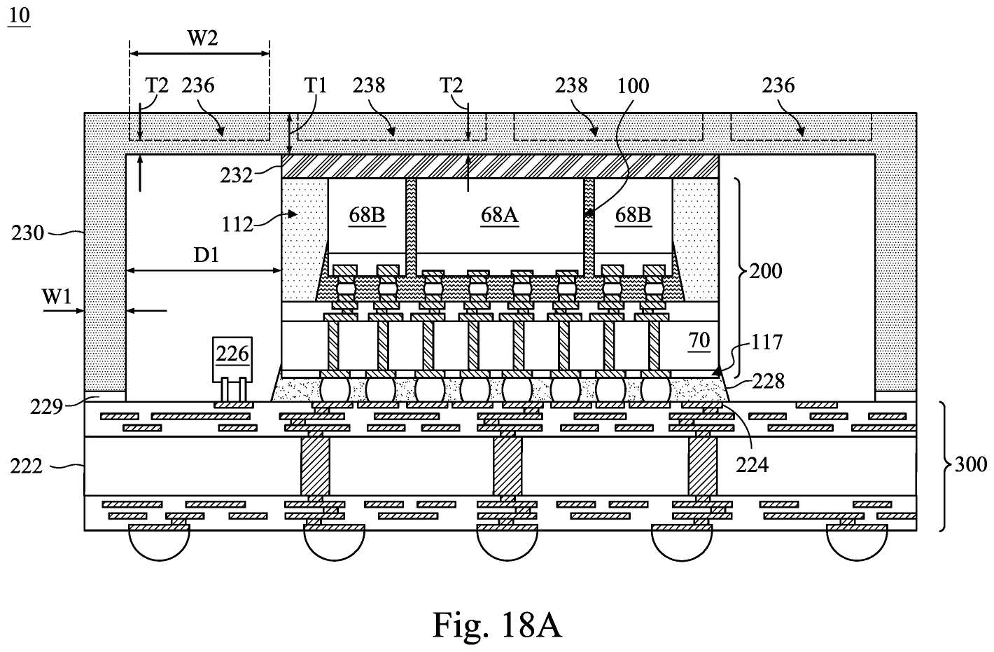

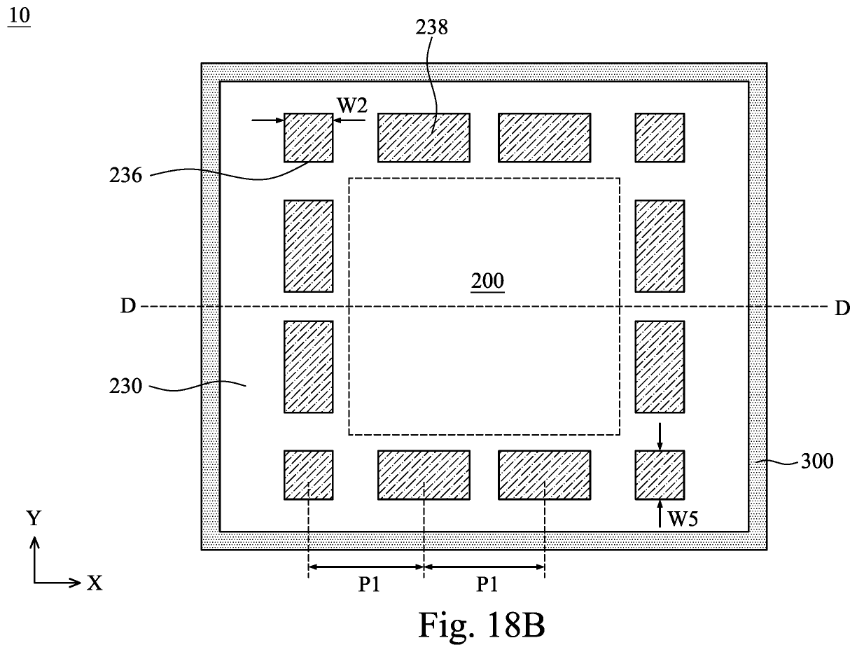

FIGS. 18A and 18B illustrate the integrated circuit package 10 in accordance with some other embodiments. FIG. 18A illustrates a cross-sectional view of the integrated circuit package 10 along the line D-D shown in FIG. 18B. FIG. 18B illustrates a top-down view of the integrated circuit package 10.

As illustrated in FIG. 18A, the top portion 230A of the heat spreader 230 comprises a top surface having a plurality of concave portions 236 that are disposed between each sidewall of the package component 200 and a nearest respective inner sidewall of the bottom portion 230B. In addition, the top portion 230A comprises a plurality of concave portions 238 between the concave portions 236. The location of the plurality of concave portions 236 and the plurality of concave portions 238 are shown in ghost in the cross-sectional view of FIG. 18A. The plurality of concave portions 236 and the plurality of concave portions 238 may also be referred to subsequently as a plurality of grooved portions or a plurality of recessed portions. In another embodiment (not separately illustrated), the plurality of concave portions 236 may overlap the bottom portion 230B. In an embodiment, at a point adjacent the plurality of concave portions 236 and 238, the top portion 230A may have a maximum thickness T1 (previously described). In an embodiment, at a point beneath the plurality of concave portions 236 and 238, the top portion 230A may have a smallest thickness T2 (previously described). As illustrated in FIG. 18B, the plurality of concave portions 236 are proximate the perimeter of the package component 200 (e.g., at the corners of the package component 200), such that the plurality of concave portions 236 do not overlap the package component 200. In an embodiment, the plurality of concave portions 238 are proximate the perimeter of the package component 200 (e.g., adjacent to sidewalls of the package component 200), such that the plurality of concave portions 236 do not overlap the package component 200. In an embodiment, each of the plurality of concave portions 236 and the plurality of concave portions 238 may comprise a square or rectangle shape in a top-down view. In an embodiment, each of the plurality of concave portions 236 may comprise the width W2 in the first direction (e.g., the x-direction) that is in a range from 3 mm to 5 mm. In an embodiment, each of the plurality of concave portions 236 may comprise a width W5 in the second direction (e.g., the y-direction) that is in a range from 3 mm to 5 mm. Each of a first subset of the plurality of concave portions 238 may comprise the width W2 in the first direction, and each of a second subset of the plurality of concave portions 238 may comprise a width larger than the width W2 in the first direction. In an embodiment, each of the second subset of the plurality of concave portions 238 may comprise the width W5 in the second direction, and each of the first subset of the plurality of concave portions 238 may comprise a width larger than the width W5 in the second direction. The width W2 may be smaller, larger, or equal to the width W5. In an embodiment, a pitch P1 between a centerline of a first of the plurality of concave portions 236 and a centerline of an adjacent one of the plurality of concave portions 238 in the first direction or the second direction is in a range from 1 mm to 5 mm. In an embodiment, a pitch between a centerline of a first of the plurality of concave portions 238 and a centerline of an adjacent one of the plurality of concave portions 238 in the first direction or the second direction is equal to the pitch P1. In an embodiment, the pitch P1 is larger than 0.2 mm.

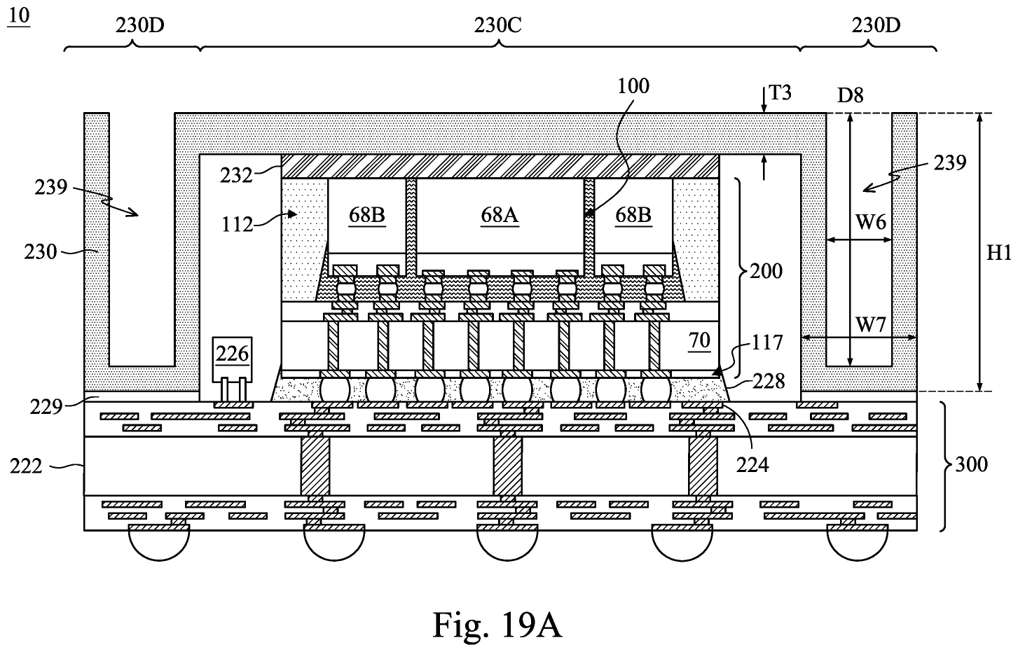

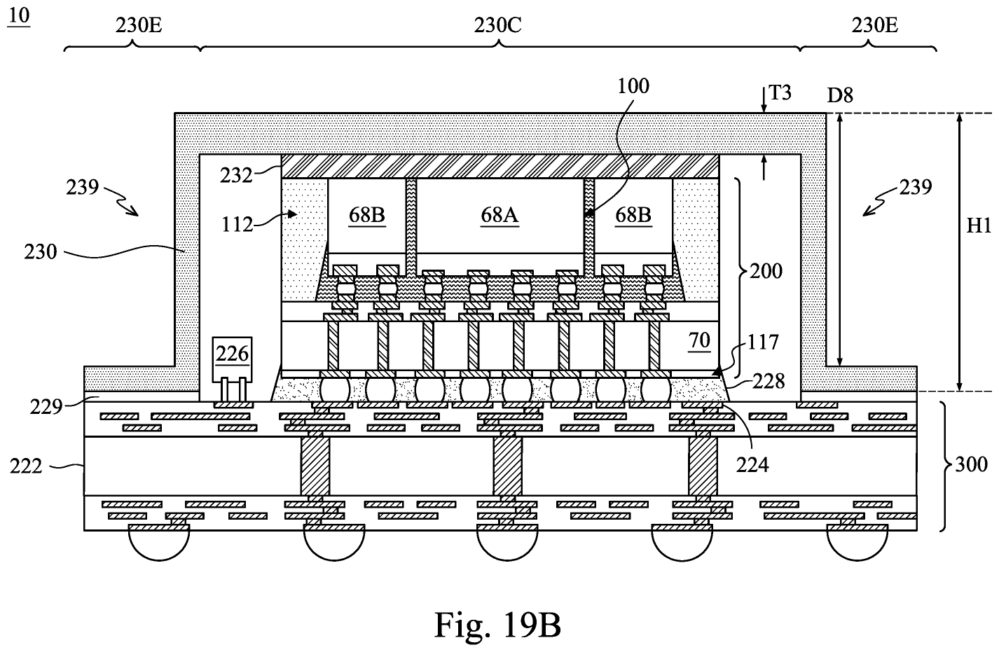

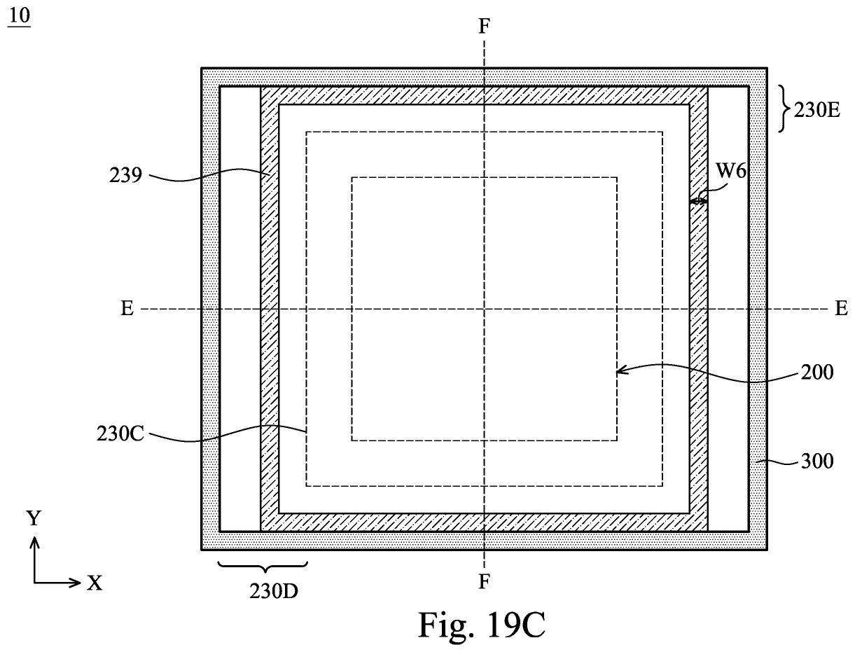

FIGS. 19A through 19C illustrate the integrated circuit package 10 in accordance with some other embodiments. FIG. 19A illustrates a cross-sectional view of the integrated circuit package 10 along the line E-E shown in FIG. 19C. FIG. 19B illustrates a cross-sectional view of the integrated circuit package 10 along the line F-F shown in FIG. 19C. FIG. 19C illustrates a top-down view of the integrated circuit package 10.

The heat spreader 230 comprises a central portion 230C, edge portions 230D, and edge portions 230E. The central portion 230C is above and in physical contact with a top surface of the package component 200 by way of the TIM 232, and the edge portions 230D and 230E are in physical contact with the substrate 300 by way of the adhesive material 229. The edge portions 230D and 230E surround the package component 200. The edge portions 230D comprise a first edge and a second edge of the heat spreader 230, and the edge portions 230E comprise a third edge and a fourth edge of the heat spreader 230, wherein the first edge of the heat spreader 230 is on an opposite side of the package component 200 as the second edge of the heat spreader 230, and wherein the third edge of the heat spreader 230 is on an opposite side of the package component 200 as the fourth edge of the heat spreader 230. As illustrated in FIGS. 19A through 19C, the central portion 230C of the heat spreader 230 is disposed such that it overlaps the package component 200 and portions of the substrate 300. Each of the edge portions 230D and the edge portions 230E comprises a top surface having a recess 239. The recess 239 may also be referred to subsequently as a groove. FIG. 19A illustrates that each recess 239 is positioned centrally in each edge portion 230D such that the recess 239 is disposed between opposite sidewalls of the edge portion 230D. FIG. 19B illustrates that each recess 239 is positioned such that is disposed adjacent to only one sidewall of a respective edge portion 230E, wherein the one sidewall of the edge portion 230E is between the package component 200 and the recess 239, and is not limited thereto. The recess 239 may extend to an outer edge of the edge portion 230E. As illustrated in FIG. 19C, the recess 239 surrounds an entirety of the perimeter of the package component 200. In an embodiment, the central portion 230C may have a thickness T3 that is in the range from 1.5 mm to 3.5 mm. In an embodiment, the heat spreader 230 may have a height H1 that is in a range from 2.5 mm to 5 mm. In an embodiment, each recess 239 in the edge portions 230D may have a width W6 that is in a range from 1 mm to 4 mm. In an embodiment, the recess 239 may have a depth D8 that is in a range from 1 mm to 4 mm. In an embodiment, each edge portion 230D may have a width W7 that is in a range from 2 mm to 5 mm. In an embodiment, the thickness T3 is smaller than the height H1. In an embodiment, the thickness T3 is smaller than the depth D8. In an embodiment, the depth D8 is smaller than the height H1. In an embodiment, the width W6 is smaller than the width W7. The depth D8 may be smaller, larger, or equal to the width W6. In an embodiment, a ratio of the depth D8 to the height H1 is larger than 0.1 but smaller than 0.99.

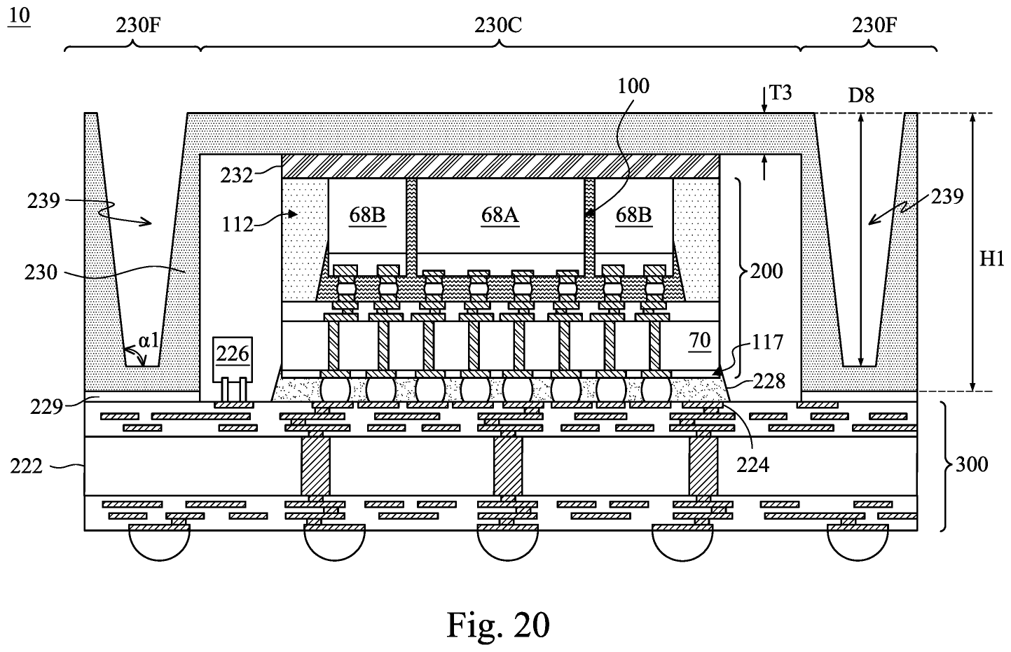

FIG. 20 illustrates the integrated circuit package 10 in accordance with some other embodiments. FIG. 20 illustrates a cross-sectional view of the integrated circuit package 10 along a line similar to the any of the lines E-E or the line F-F shown in FIG. 19C.

The heat spreader 230 comprises a central portion 230C and edge portions 230F. The central portion 230C is above and in physical contact with a top surface of the package component 200 by way of the TIM 232 and the edge portions 230F are in physical contact with the substrate 300 by way of the adhesive material 229. The edge portions 230F comprise a first edge and a second edge of the heat spreader 230, wherein the first edge of the heat spreader 230 is on an opposite side of the package component 200 as the second edge of the heat spreader 230. As illustrated in FIG. 20, the central portion 230C of the heat spreader 230 is disposed such that it overlaps the package component 200 and portions of the substrate 300. Each of the edge portions 230F comprises a top surface having the recess 239. The recess 239 may also be referred to subsequently as a groove. FIG. 20 illustrates that each recess 239 is positioned centrally in each edge portion 230F such that the recess 239 is disposed between opposite sidewalls of the edge portion 230F. An angle α1 between a bottom surface of the recess 239 and each opposing sidewall of the recess 239 is an obtuse angle. In an embodiment, the angle α1 is in the range of 90° and 180°.

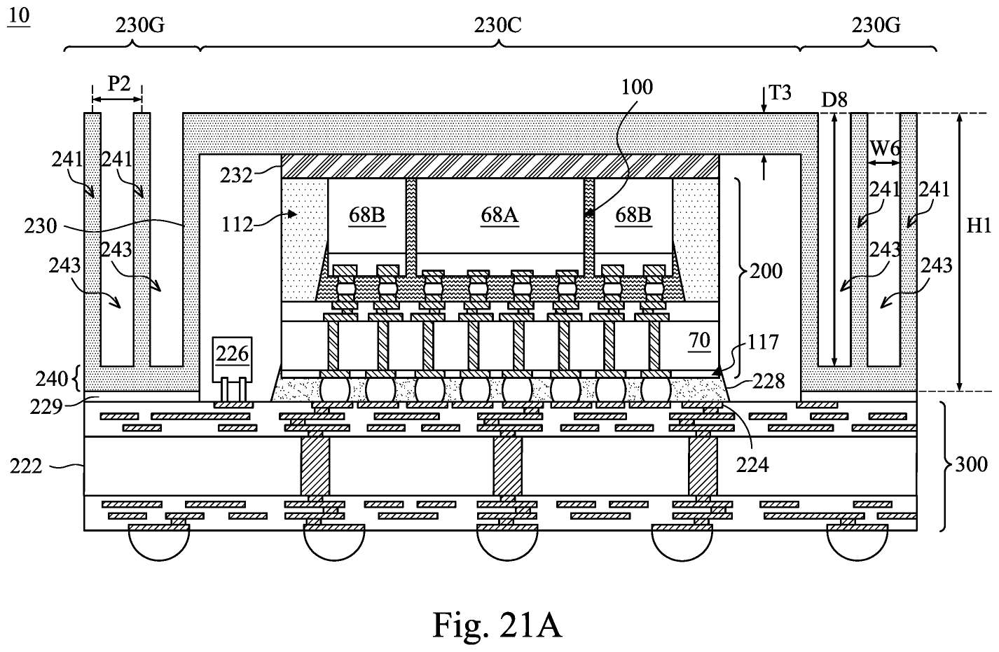

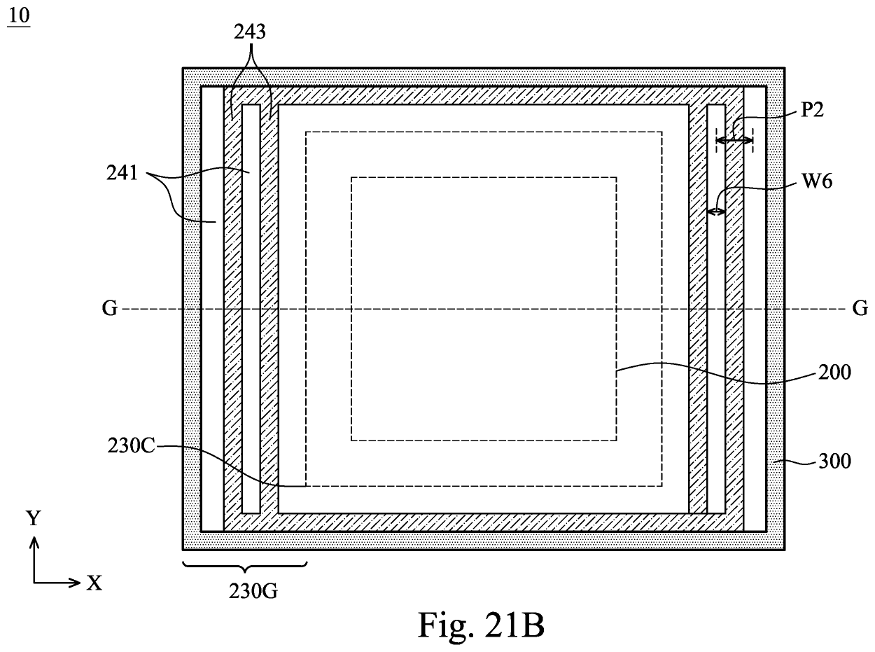

FIGS. 21 and 21B illustrate the integrated circuit package 10 in accordance with some other embodiments. FIG. 21A illustrates a cross-sectional view of the integrated circuit package 10 along a line G-G shown in FIG. 21B. FIG. 21B illustrates a top-down view of the integrated circuit package 10.

The heat spreader 230 comprises a central portion 230C and edge portions 230G. The central portion 230C is above and in physical contact with a top surface of the package component 200 by way of the TIM 232 and the edge portions 230G are in physical contact with the substrate 300 by way of the adhesive material 229. The edge portions 230G comprise a first edge and a second edge of the heat spreader 230, wherein the first edge of the heat spreader 230 is on an opposite side of the package component 200 as the second edge of the heat spreader 230. Each of the edge portions 230G may comprise a bottom portion 240 having a plurality of protruding strips 241 on the bottom portion 240, where adjacent protruding strips 241 are separated by a recess 243 in the heat spreader 230. Although FIGS. 21A and 21B illustrate that each edge portion 230G has plurality of protruding strips 241 that includes two protruding strips, the plurality of protruding strips 241 may comprise any number of protruding strips. The plurality of protruding strips 241 may extend to an outer edge of each edge portion 230G, such that a sidewall of the outer protruding strip of the plurality of protruding strips 241 is coterminous with a sidewall of the bottom portion 240 below the plurality of protruding strips 241. In an embodiment, top surfaces of the plurality of protruding strips 241 are level with a top surface of the central portion 230C. As illustrated in FIG. 21A, the central portion 230C of the heat spreader 230 is disposed such that it overlaps the package component 200 and portions of the substrate 300. In an embodiment, a height of each protruding strip of the plurality of protruding strips 241 may be equal to the depth D8 (previously described). In an embodiment, a width between a sidewall of a first protruding strip of the plurality of protruding strips 241 and a sidewall of an adjacent protruding strip of the plurality of protruding strips 241 is equal to the width W6 (previously described). A pitch P2 between a centerline of the first protrusion of the plurality of protruding strips 241 and a centerline of an adjacent protrusion of the plurality of protruding strips 241 may be in a range from 0.5 mm to 2 mm. In an embodiment, the pitch P2 may be may be larger than 0.2 mm and larger than the width W6.

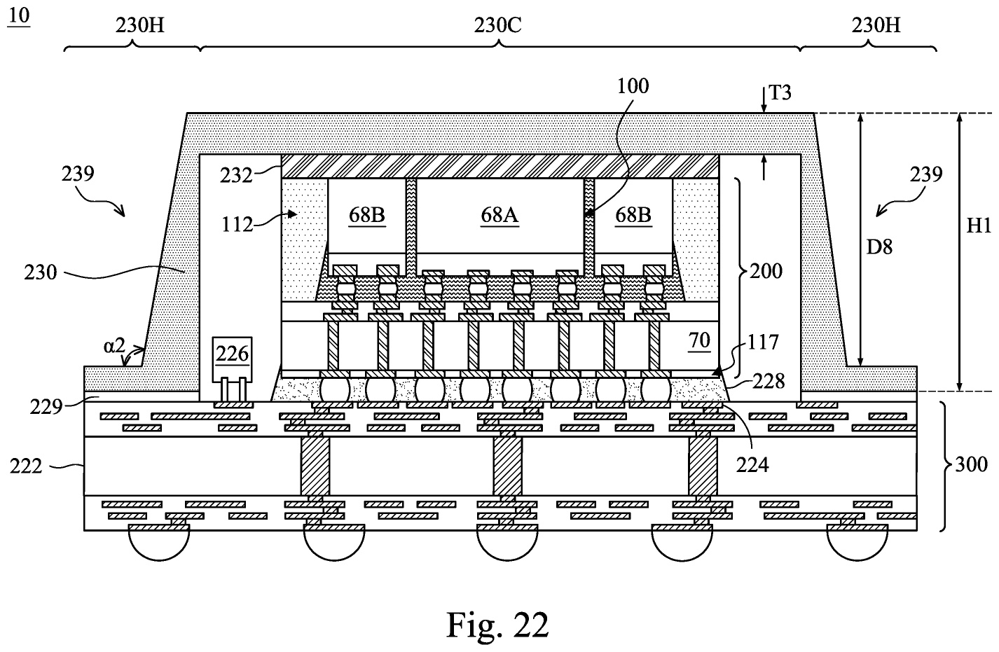

FIG. 22 illustrates the integrated circuit package 10 in accordance with some other embodiments. FIG. 22 illustrates a cross-sectional view of the integrated circuit package 10 along a line similar to the any of the lines E-E or the line F-F shown in FIG. 19C.

The heat spreader 230 comprises a central portion 230C and edge portions 230H. The central portion 230C is above and in physical contact with a top surface of the package component 200 by way of the TIM 232 and the edge portions 230H are in physical contact with the substrate 300 by way of the adhesive material 229. The edge portions 230H comprise a first edge and a second edge of the heat spreader 230, wherein the first edge of the heat spreader 230 is on an opposite side of the package component 200 as the second edge of the heat spreader 230. As illustrated in FIG. 22, the central portion 230C of the heat spreader 230 is disposed such that it overlaps the package component 200 and portions of the substrate 300. Each of the edge portions 230H comprises a top surface having a recess 239. The recess 239 may also be referred to subsequently as a groove. FIG. 22 illustrates that each recess 239 is positioned such that is disposed adjacent to only one sidewall of a respective edge portion 230H, wherein the one sidewall of the edge portion 230H is between the package component 200 and the recess 239, and is not limited thereto. The recess 239 extends to an outer edge of the edge portion 230H. An angle α2 between a bottom surface of the recess 239 and the one sidewall of the recess 239 is an obtuse angle. In an embodiment, the angle α2 is in the range of 90° and 180°.

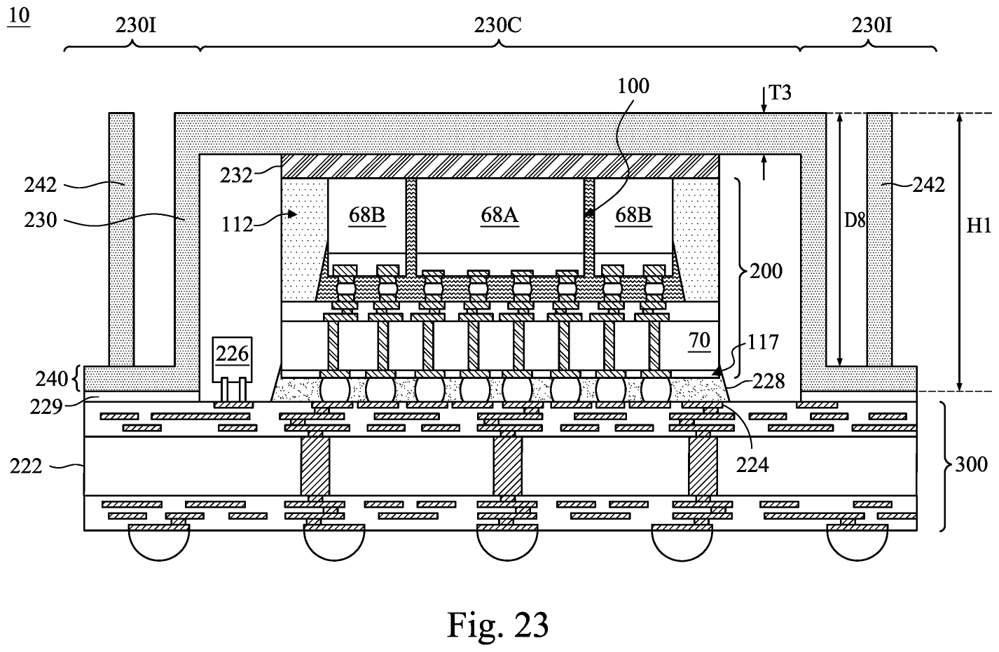

FIG. 23 illustrates the integrated circuit package 10 in accordance with some other embodiments. FIG. 23 illustrates a cross-sectional view of the integrated circuit package 10 along a line similar to the any of the lines E-E or the line F-F shown in FIG. 19C.

The heat spreader 230 comprises a central portion 230C and edge portions 230I. The central portion 230C is above and in physical contact with a top surface of the package component 200 by way of the TIM 232 and the edge portions 230I are in physical contact with the substrate 300 by way of the adhesive material 229. The edge portions 230I comprise a first edge and a second edge of the heat spreader 230, wherein the first edge of the heat spreader 230 is on an opposite side of the package component 200 as the second edge of the heat spreader 230. Each of the edge portions 230I may comprise a bottom portion 240 having a protruding strip 242 on the bottom portion 240. The protruding strip 242 may be disposed between an outer edge of the edge portion 230I and the central portion 230C, such that an outer sidewall of the protruding strip 242 and an outer sidewall of the bottom portion 240 below the protruding strip 242 are not coterminous. In an embodiment, top surfaces of the protruding strips 242 are level with a top surface of the central portion 230C. As illustrated in FIG. 23, the central portion 230C of the heat spreader 230 is disposed such that it overlaps the package component 200 and portions of the substrate 300. In an embodiment, a height of each protruding strip 242 may be equal to the depth D8 (previously described).

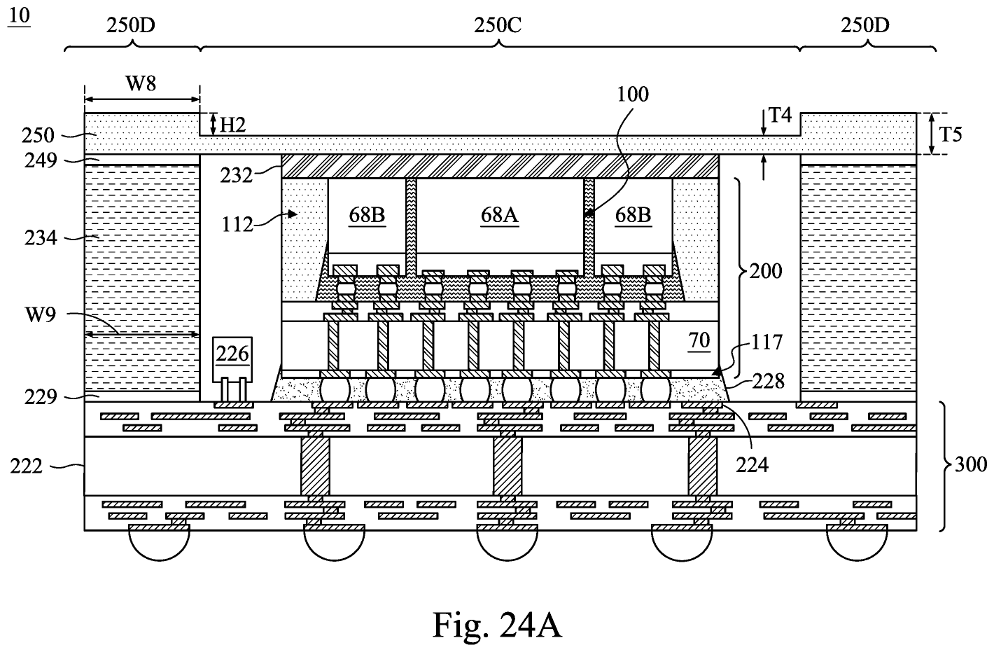

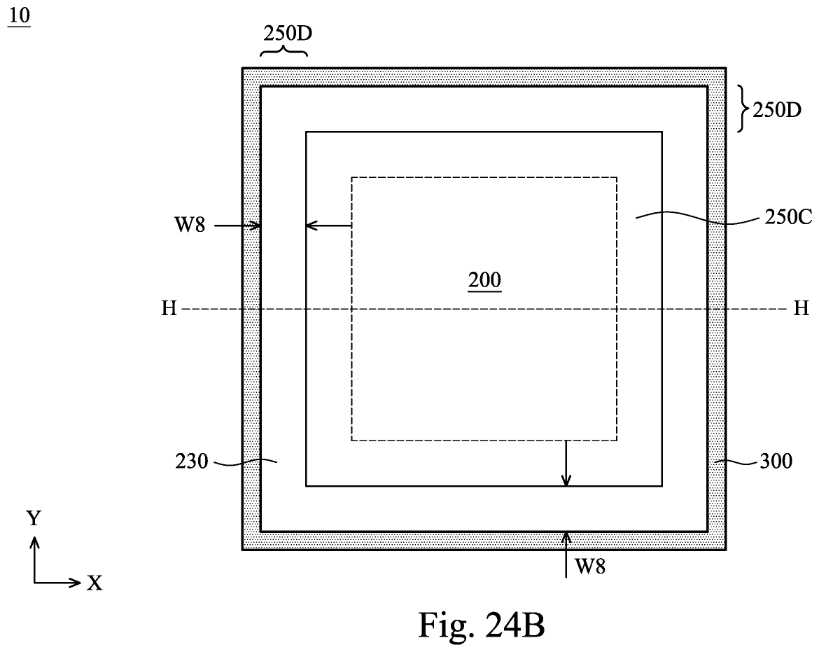

FIGS. 24A and 24B illustrate the integrated circuit package 10 in accordance with some other embodiments. FIG. 24A illustrates a cross-sectional view of the integrated circuit package 10 along the line H-H shown in FIG. 24B. FIG. 24B illustrates a top-down view of the integrated circuit package 10.

In FIGS. 24A and 24B, a ring 234 is placed on the substrate 300. The ring 234 is placed such that it surrounds the surface devices 226 and the package component 200. The ring 234 is thermally coupled to the substrate 300 through the adhesive material 229. The ring 234 may be formed of a first material with high thermal conductivity, such as a metal, such as copper, steel, iron, or the like. In an embodiment, the first material of the ring 234 may have a first coefficient of thermal expansion that is in a range from 1×10⁻⁶ 1/C. ° to 30×10⁻⁶ 1/C. °. The ring 234 protects the package component 200 and forms a thermal pathway to conduct heat from the various components of the package component 200 (e.g., the substrate 300).

After the ring 234 is placed on the substrate 300, an adhesive material 249 is dispensed on top surfaces of the ring 234. The adhesive material 249 may be similar to the adhesive material 229 (previously described in FIG. 13). A heat spreader 250 is then placed on the ring 234. The heat spreader 250 may be a thermal lid, a thermal ring, or the like. The heat spreader covers the package component 200, the package component 200, and the ring 234. The heat spreader 230 may be formed of a second material with high thermal conductivity, such as a metal, such as copper, steel, iron, or the like. In an embodiment, the second material of the heat spreader 250 may have a second coefficient of thermal expansion that is in a range 1×10⁻⁶ 1/C. ° to 30×10⁻⁶ 1/C. °. In an embodiment, the first material is different from the second material. In an embodiment, the first coefficient of thermal expansion of the first material of the ring 234 and the second coefficient of thermal expansion of the second material of the heat spreader 250 may be different, which helps to compensate for differences in coefficients of thermal expansion between the package component 200 and the substrate 300. This results in a reduction of stress in the underfill material 100 that is disposed between adjacent dies 68. The heat spreader 250 and the ring 234 protect the package component 200 and form a thermal pathway to conduct heat from the various components of the package component 200 (e.g., the dies 68). The heat spreader 250 is thermally coupled to the back-side surface of the package component 200 through the TIM 232, and coupled to the substrate 300 through the adhesive material 229, the adhesive material 249, and the ring 234. The adhesive material 249 may be cured during the process for curing the adhesive material 229 (previously described).

The heat spreader 250 comprises a central portion 250C and an edge portion 250D. The edge portion 250D surrounds the central portion 250C. The central portion 250C and the edge portion 250D are above top surfaces of the ring 234 and the package component 200. The central portion 250C overlaps the package component 200 and portions of the substrate 300, and the central portion 250C has a top surface that is recessed to be lower than top surface of the edge portion 250D. In the cross-sectional view of FIG. 24A, the combined structure of the heat spreader 250 and the ring 234 has a H-shaped cross-sectional profile. The central portion 250C is in physical contact with a top surface of the package component 200 by way of the TIM 232, and the edge portion 250D overlaps and is in physical contact with the ring 234 by way of the adhesive material 249. As shown in FIG. 24B, the edge portion 250D extends along an entirety of the perimeter of the package component 200. In an embodiment, the central portion 250C have a thickness T4 that is in a range from 0.5 mm to 1.5 mm. In an embodiment, the top surface of the central portion 250C is lower than the top surface of the edge portion 250D by a height H2, wherein the thickness T4 is smaller than the height H2. In an embodiment, the edge portion 250D may have a thickness T5, wherein the thickness T4 is smaller than the thickness T5. In an embodiment, the thickness T5 is in a range from 1.5 mm to 3.5 mm. In an embodiment, each edge portion 250D has a width W8, and a difference between an outer radius and inner radius of the ring 234 is equal to a width W9, wherein the width W8 is equal to the width W9. As such, the inner sidewalls of the ring 234 are aligned with the inner sidewalls of the edge portion 250D, and the outer sidewalls of the ring 234 are aligned with the outer sidewalls of the edge portion 250D. In an embodiment, the thickness T4 and the thickness T5 are in the range of 0.2 mm and 3 mm. In an embodiment, the width W8 and the width W9 are in the range of 0.2 mm and 10 mm.

Advantages may be achieved as a result of the integrated circuit package 10 comprising a ring 234 that surrounds the package component 200, and a heat spreader 250 on the ring 234 and the package component 200. These advantages include a reduction of stress in the underfill material 100 disposed between adjacent dies 68. This results in a reduced risk of delamination between adjacent dies 68 and the underfill material 100, which improves device reliability.

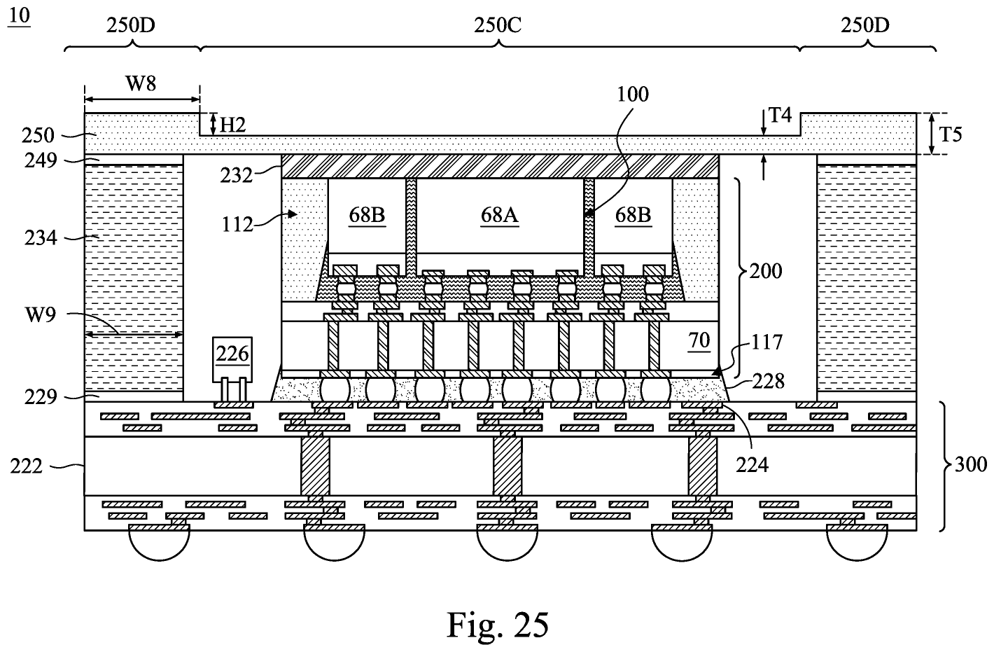

FIG. 25 illustrates an integrated circuit package 10 in accordance with some other embodiments. This embodiment is similar to the embodiment of FIG. 24A, except the thickness T4 is greater than the height H2. Further, the width W8 of each edge portion 250D is greater than the width W9 of the ring 234. In an embodiment, an outer sidewall of each edge portion 250D is aligned with a respective outer sidewall of the ring 234, but an inner sidewall of each edge portion 250D is offset from a respective inner sidewall of the ring 234. Specifically, the inner sidewall of each edge portion 250D is further from the edges of the integrated circuit package 10 than the inner sidewalls of the ring 234.

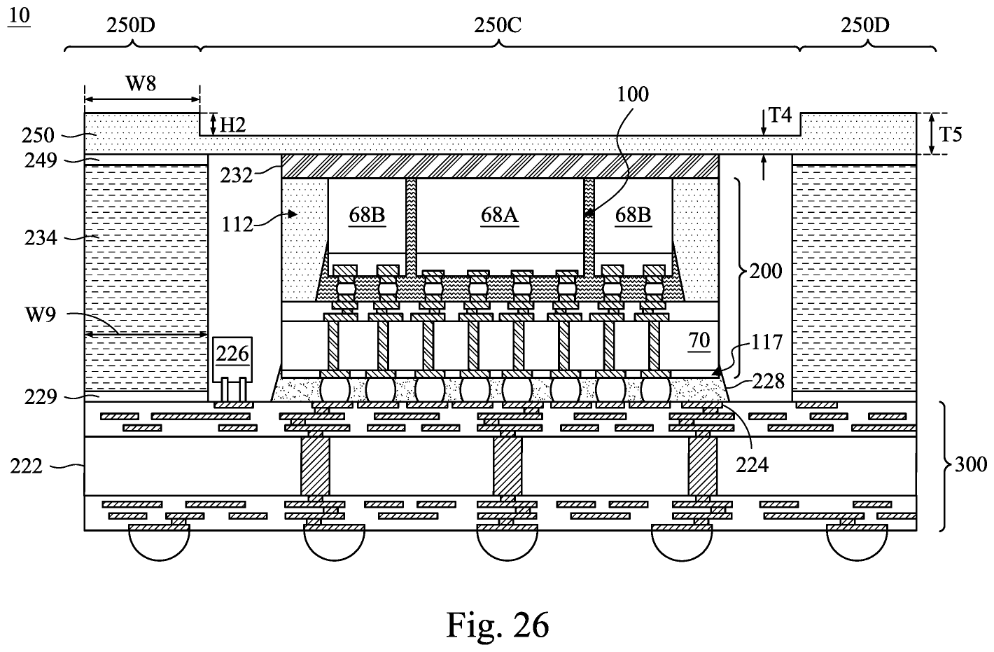

FIG. 26 illustrates an intermediate stage in the manufacturing of an integrated circuit package 10 in accordance with some other embodiments. This embodiment is similar to the embodiment of FIG. 24A, except that the width W8 of each edge portion 250D is smaller than the width W9 (e.g., the difference between an outer radius and inner radius) of the ring 234. In an embodiment, an outer sidewall of each edge portion 250D is aligned with a respective outer sidewall of the ring 234, but an inner sidewall of each edge portion 250D is offset from a respective inner sidewall of the ring 234. Specifically, the inner sidewall of each edge portion 250D is closer to the edges of the integrated circuit package 10 than the inner sidewalls of the ring 234.

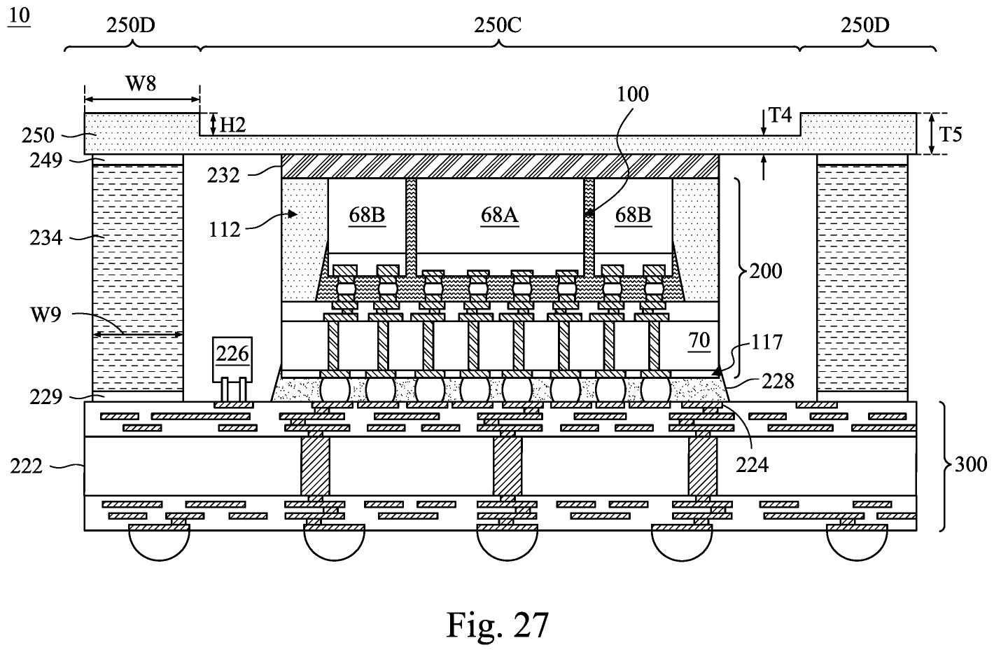

FIG. 27 illustrates an integrated circuit package 10 in accordance with some other embodiments. This embodiment is similar to the embodiment of FIG. 24A, except that the width W8 of each edge portion 250D is larger than the width W9 of the ring 234. In an embodiment, an outer sidewall of each edge portion 250D is offset from a respective outer sidewall of the ring 234. Specifically, the outer sidewall of each edge portion 250D is closer to the edges of the integrated circuit package 10 than the outer sidewalls of the ring 234. In addition, an inner sidewall of each edge portion 250D is offset from a respective inner sidewall of the ring 234. Specifically, the inner sidewall of each edge portion 250D is further from the edges of the integrated circuit package 10 than the inner sidewalls of the ring 234.

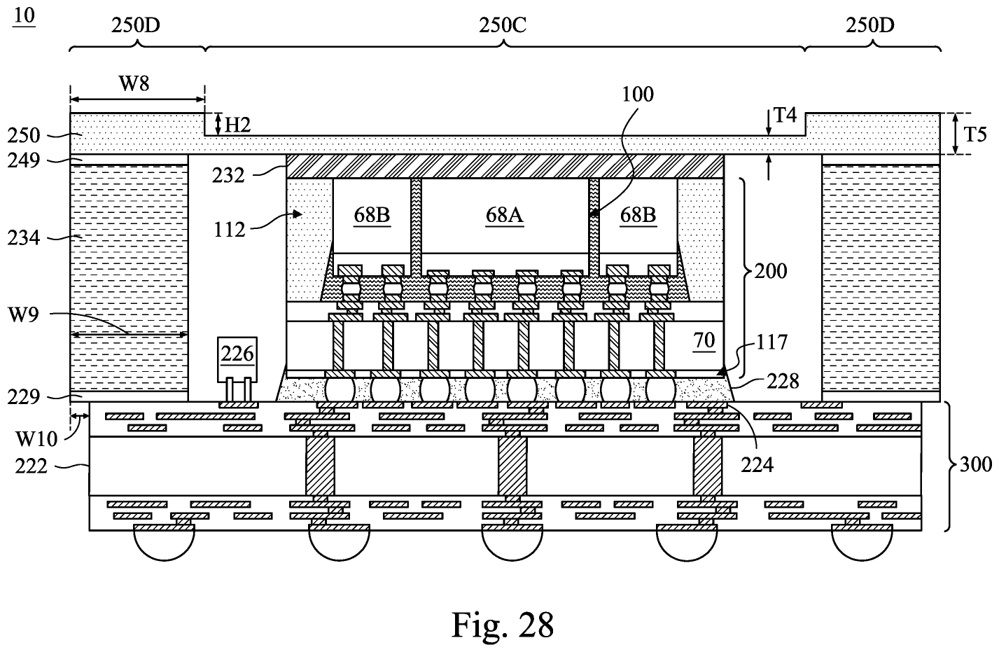

FIG. 28 illustrates an integrated circuit package 10 in accordance with some other embodiments. This embodiment is similar to the embodiment of FIG. 24A, except that the width W8 of each edge portion 250D is larger than the width W9 of the ring 234. In an embodiment, an inner sidewall of each edge portion 250D is offset from a respective inner sidewall of the ring 234. Specifically, the inner sidewall of each edge portion 250D is further from the edges of the integrated circuit package 10 than the inner sidewalls of the ring 234. In addition, the outer sidewalls of the ring 234 are aligned with the outer sidewalls of the edge portion 250D. Further, outer sidewalls of the edge portion 250D and outer sidewalls of the ring 234 are offset from and overhang a sidewall of the substrate 300 by a distance D9, wherein the distance D9 is in the range of 0 μm and 500 μm.

In accordance with an embodiment, a device includes a package substrate; an interposer having a first side bonded to the package substrate; a first die bonded to a second side of the interposer, the second side being opposite the first side; a ring on the package substrate, where the ring surrounds the first die and the interposer; and a heat spreader over and coupled to the ring and the first die, where a first coefficient of thermal expansion of a first material of the ring and a second coefficient of thermal expansion of a second material of the heat spreader are different, and where in a cross-sectional view a combined structure of the heat spreader and the ring have a H-shaped profile. In an embodiment, the heat spreader is coupled to the first die with a thermal interface material, and where the heat spreader is coupled to the ring with an adhesive material. In an embodiment, the heat spreader includes a central portion overlapping the first die; and edge portions that surround the central portion when seen in a top-down view, where a thickness of the central portion is smaller than a thickness of the edge portions. In an embodiment, a topmost surface of the central portion is lower than topmost surfaces of the edge portions. In an embodiment, a difference in height between the topmost surfaces of the edge portions and the topmost surface of the central portion is greater than the thickness of the central portion. In an embodiment, a difference in height between the topmost surfaces of the edge portions and the topmost surface of the central portion is less than the thickness of the central portion. In an embodiment, a width of each edge portion and a difference between an outer radius and an inner radius of the ring are equal.

In accordance with an embodiment, a device includes a package component comprising an interposer; and a first die connected to the interposer; a substrate connected to the interposer, where the interposer is disposed between the first die and the substrate; a heat dissipation structure over and coupled to the package component and the substrate, the heat dissipation structure having a first height, where the heat dissipation structure includes a central portion overlapping and adhered to the package component; and first edge portions on opposite sides of the package component, where the first edge portions are adhered to the substrate, where each of the first edge portions includes a first recess having a first depth, and where the first depth is less than the first height. In an embodiment, a ratio of the first depth to the first height is larger than 0.1 and smaller than 0.99. In an embodiment, a first angle between a bottom surface of the first recess and a sidewall of the first recess is an obtuse angle. In an embodiment, a thickness of the central portion is smaller than the first depth. In an embodiment, the heat dissipation structure further includes second edge portions on opposite sides of the package component, where the second edge portions are coupled to the substrate, and where each of the second edge portions includes a second recess having a second depth, where each second recess extends to an outer edge of a respective second edge portion. In an embodiment, a second angle between a bottom surface of the second recess and a sidewall of the second recess is an obtuse angle.

In accordance with an embodiment, a method includes attaching a package component to a substrate; attaching a heat dissipation structure to the package component and the substrate, where the heat dissipation structure includes a top portion overlapping the package component and the substrate, the top portion being above the package component; and a bottom portion surrounding the package component, the bottom portion being disposed between the top portion and the substrate, where the top portion includes a edge portion with a first thickness and a central portion with a second thickness that is smaller than the first thickness, the edge portion surrounding the central portion and overlapping the bottom portion. In an embodiment, the bottom portion of the heat dissipation structure includes a ring that is adhered to the top portion of the heat dissipation structure using an adhesive material. In an embodiment, a first coefficient of thermal expansion of a first material of the top portion of the heat dissipation structure is different from a second coefficient of thermal expansion of a second material of the bottom portion of the heat dissipation structure. In an embodiment, a width of the edge portion is greater than a difference between an outer radius and an inner radius of the ring, and where an outer sidewall of the edge portion is aligned with an outer sidewall of the ring. In an embodiment, an outer sidewall of the edge portion is aligned with an outer sidewall of the ring, and where the outer sidewall of the edge portion and the outer sidewall of the ring are offset from and overhang a sidewall of the substrate. In an embodiment, a width of the edge portion is equal to a difference between an outer radius and an inner radius of the ring, where an outer sidewall of the edge portion is aligned with an outer sidewall of the ring, and where an inner sidewall of the edge portion is aligned with an inner sidewall of the ring. In an embodiment, the top portion of the heat dissipation structure and the bottom portion of the heat dissipation structure include the same continuous material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a package substrate;
an interposer having a first side bonded to the package substrate;
a first die bonded to a second side of the interposer, the second side being opposite the first side;
a ring on the package substrate, wherein the ring surrounds the first die and the interposer; and
a heat spreader over and coupled to the ring and the first die, wherein a first coefficient of thermal expansion of a first material of the ring and a second coefficient of thermal expansion of a second material of the heat spreader are different, and wherein in a cross-sectional view a combined structure of the heat spreader and the ring have a H-shaped profile.

2. The device of claim 1, wherein the heat spreader is coupled to the first die with a thermal interface material, and wherein the heat spreader is coupled to the ring with an adhesive material.

3. The device of claim 1, wherein in the heat spreader comprises:
a central portion overlapping the first die; and
edge portions that surround the central portion when seen in a top-down view, wherein a thickness of the central portion is smaller than a thickness of the edge portions.

4. The device of claim 3, wherein a topmost surface of the central portion is lower than topmost surfaces of the edge portions.

5. The device of claim 4, wherein a difference in height between the topmost surfaces of the edge portions and the topmost surface of the central portion is greater than the thickness of the central portion.

6. The device of claim 4, wherein a difference in height between the topmost surfaces of the edge portions and the topmost surface of the central portion is less than the thickness of the central portion.

7. The device of claim 4, wherein a width of each edge portion and a difference between an outer radius and an inner radius of the ring are equal.

8. A device comprising:
a package component comprising:
an interposer; and
a first die connected to the interposer;
a substrate connected to the interposer, wherein the interposer is disposed between the first die and the substrate;
a heat dissipation structure over and coupled to the package component and the substrate, the heat dissipation structure having a first height, wherein the heat dissipation structure comprises:
a central portion overlapping and adhered to the package component; and
first edge portions on opposite sides of the package component, wherein the first edge portions are adhered to the substrate, wherein each of the first edge portions comprises a first recess having a first depth, and wherein the first depth is less than the first height.

9. The device of claim 8, wherein a ratio of the first depth to the first height is larger than 0.1 and smaller than 0.99.

10. The device of claim 8, wherein a first angle between a bottom surface of the first recess and a sidewall of the first recess is an obtuse angle.

11. The device of claim 8, wherein a thickness of the central portion is smaller than the first depth.

12. The device of claim 8, wherein the heat dissipation structure further comprises:
second edge portions on opposite sides of the package component, wherein the second edge portions are coupled to the substrate, and wherein each of the second edge portions comprises a second recess having a second depth, wherein each second recess extends to an outer edge of a respective second edge portion.

13. The device of claim 12, wherein a second angle between a bottom surface of the second recess and a sidewall of the second recess is an obtuse angle.

14. A method comprising:
attaching a package component to a substrate;
attaching a heat dissipation structure to the package component and the substrate, wherein the heat dissipation structure comprises:
a top portion overlapping the package component and the substrate, the top portion being above the package component; and
a bottom portion surrounding the package component, the bottom portion being disposed between the top portion and the substrate, wherein the top portion comprises a edge portion with a first thickness and a central portion with a second thickness that is smaller than the first thickness, the edge portion surrounding the central portion and overlapping the bottom portion.

15. The method of claim 14, wherein the bottom portion of the heat dissipation structure comprises a ring that is adhered to the top portion of the heat dissipation structure using an adhesive material.

16. The method of claim 15, wherein a first coefficient of thermal expansion of a first material of the top portion of the heat dissipation structure is different from a second coefficient of thermal expansion of a second material of the bottom portion of the heat dissipation structure.

17. The method of claim 15, wherein a width of the edge portion is greater than a difference between an outer radius and an inner radius of the ring, and wherein an outer sidewall of the edge portion is aligned with an outer sidewall of the ring.

18. The method of claim 15, wherein an outer sidewall of the edge portion is aligned with an outer sidewall of the ring, and wherein the outer sidewall of the edge portion and the outer sidewall of the ring are offset from and overhang a sidewall of the substrate.

19. The method of claim 15, wherein a width of the edge portion is equal to a difference between an outer radius and an inner radius of the ring, wherein an outer sidewall of the edge portion is aligned with an outer sidewall of the ring, and wherein an inner sidewall of the edge portion is aligned with an inner sidewall of the ring.

20. The method of claim 14, wherein the top portion of the heat dissipation structure and the bottom portion of the heat dissipation structure comprise the same continuous material.
